(19) United States
(12) Patent Application Publication
(10) Pub. No.: US 2010/0299579 A1
(43) Pub. Date: Nov. 25, 2010

(54) Methods and Systems for Error-Correction in Convolutional and Systematic Convolutional Decoders in Galois Configuration

(75) Inventor: Peter Lablans, Morris Township, NJ (US)

Correspondence Address: DIEHL SERVILLA LLC, 33 WOOD AVE SOUTH, SECOND FLOOR, SUITE 210, ISELIN, NJ, 08830, US

(73) Assignee: Ternarylogic LLC, Morristown, NJ (US)

(21) Appl. No.: 12/774,092

(22) Filed: May 5, 2010

Related U.S. Application Data
(60) Provisional application No. 61/180,159, filed on May 21, 2009.

(51) Int. Cl. H03M 13/07; G06F 11/10

(52) U.S. Cl. 714/781; 714/E11.033

(57) ABSTRACT

Convolutional coders having an n-state with n≧2 Linear Feedback Shift Registers (LFSR) in Galois configuration with k shift register elements with k>1 are provided. Corresponding decoders are also provided. A convolutional coder generates a sequence of coded n-state symbols. A content of a starting position of an LFSR in a decoder is determined when sufficient error free coded symbols are available. Up to k symbols in error are corrected. A systematic convolutional coder and decoder are also provided.

### RELATED MATTER

This application claims the benefit of U.S. Provisional Patent Application Ser. No. 61/180,159 filed on May 21, 2009, with the same title as the present application and which is hereby incorporated herein by reference in its entirety.

### BACKGROUND OF THE INVENTION

The present invention relates to binary and n-valued Linear Feedback Shift Registers (LFSRs) based convolutional coders and decoders in Galois configuration.

One is referred to U.S. patent application Ser. No. 11/566,725, filed on Dec. 5, 2006, which is incorporated herein by reference in its entirety, including all references that are incorporated therein by reference, for the background on standard and modified binary and n-valued convolutional coders and decoders as developed by the inventor.

In general, in sending a sequence of binary or n-valued symbols one may want to repeat the sequence to detect errors. By scrambling one or both sequences one may also be able to correct errors. The standard convolutional coders are LFSR based descramblers in Fibonacci configuration.

Encoders in Galois configuration work faster when more than 1 tap is applied in the feedback loop of the LFSR.

Accordingly, novel and improved method are required to provide Galois based coders and decoders.

### SUMMARY OF THE INVENTION

In the context of the present invention the term n-valued is used. In general n is intended to indicate a state of a signal or a symbol with n>2, unless it is specifically mentioned that n≧2. Symbols may represent a signal. A signal may also represent an n-state or n-valued symbol. A plurality of signals may also represent an n-state or n-valued symbol. The term symbol and signal may be used interchangeably. An n-valued symbol or signal is able to assume one state at a time, wherein the symbol or signal assumes one of n possible states. In general n states may be indicated with values from 0 to (n−1). A state signifies only that it is different from another state. While a state of a symbol may be represented by a signal, a state does not reflect the actual value of a signal. An exception herein may be the state 0, which in certain cases may reflect absence of signal. A symbol which is indicated as being able to assume one of n states, is intended to be able assume at a time any of the n possible states. In some cases a symbol may be able to only or at least assume a limited number of states. In that case it may be mentioned that a symbol can assume for instance a first or a second state.

In accordance with one aspect of the present invention a convolutional coder and decoder is provided for error correction of symbols in error.

In accordance with a further aspect of the present invention a method is provided for decoding with a processor a first coded sequence of p n-state symbols with p and n being integers greater or equal to 2, comprising generating the first coded sequence from an uncoded sequence of p n-state symbols by a first coder equivalent to a first n-state descrambler with a first n-state Linear Feedback Shift Register (LFSR) in Galois configuration having k shift register elements with k being an integer greater than 1, determining a start state of a shift register of a first decoder corresponding to the first coder by processing at least k symbols of the first coded sequence and at least k symbols of a second sequence related to the uncoded sequence, and decoding the first coded sequence into a first decoded sequence with the first decoder by applying the start state.

In accordance with yet a further aspect of the present invention a method is provided, wherein the second sequence is the uncoded sequence.

In accordance with yet a further aspect of the present invention a method is provided, wherein the second sequence is generated from the uncoded sequence by a second coder equivalent to a second n-state descrambler with a second n-state Linear Feedback Shift Register (LFSR) in Galois configuration having at least k shift register elements with k being an integer greater than 1, and determining a start state of the shift register of the first decoder corresponding to the first coder by processing at least 2*k symbols of the first coded sequence and at least 2*k symbols of the second sequence.

In accordance with yet a further aspect of the present invention a method is provided, further comprising storing a first state of the shift register of the first n-state shift register of the first decoder when corresponding symbols in the first coded sequences and the second sequence indicate an error, and correcting up to k symbols in error in the first decoded sequence by processing the first state and the start state by the processor.

In accordance with yet a further aspect of the present invention a method is provided, wherein an n-state symbol is represented by an n-state signal able to assume one of n states.

In accordance with yet a further aspect of the present invention a method is provided, wherein an n-state symbol is represented by a binary word, and a decoder is implemented by using binary circuitry.

In accordance with yet a further aspect of the present invention a method is provided, wherein n=2q with q and integer equal to 1 or greater than 1.

In accordance with yet a further aspect of the present invention a method is provided, wherein the method is applied in a communication system.

In accordance with yet a further aspect of the present invention a method is provided, wherein the method is applied in a data storage system.

In accordance with another aspect of the present invention a method is provided for decoding with a processor a first coded sequence of p n-state symbols with p and n being integers greater or equal to 2, comprising generating the first coded sequence from an uncoded sequence of p n-state symbols by a first coder equivalent to a first n-state descrambler with a first n-state Linear Feedback Shift Register (LFSR) in Fibonacci configuration having k shift register elements with k being an integer greater than 1, determining a start state of a shift register of a first decoder corresponding to the first coder by processing k symbols of the first coded sequence and k symbols of the uncoded sequence, and decoding the first coded sequence into a first decoded sequence with the first decoder by applying the start state.

In accordance with a further aspect of the present invention a system is provided for decoding a first coded sequence of p n-state symbols with p and n being integers greater or equal to 2, comprising a memory for storing and providing data and instructions a processor for executing instructions retrieved from the memory to perform the steps of generating the first coded sequence from an uncoded sequence of p n-state symbols by a first coder equivalent to a first n-state descrambler with a first n-state Linear Feedback Shift Register (LFSR) in Galois configuration having k shift register elements with k being an integer greater than 1, determining a start state of a shift register of a first decoder corresponding to the first coder by processing at least k symbols of the first coded sequence and at least k symbols of a second sequence related to the uncoded sequence, and decoding the first coded sequence into a first decoded sequence with the first decoder by applying the start state.

In accordance with yet a further aspect of the present invention a system is provided, wherein the second sequence is the uncoded sequence.

In accordance with yet a further aspect of the present invention a system is provided, wherein the second sequence is generated from the uncoded sequence by a second coder equivalent to a second n-state descrambler with a second n-state Linear Feedback Shift Register (LFSR) in Galois configuration having at least k shift register elements with k being an integer greater than 1, and determining a start state of the shift register of the first decoder corresponding to the first coder by processing at least 2*k symbols of the first coded sequence and at least 2*k symbols of the second sequence.

In accordance with yet a further aspect of the present invention a system is provided, further comprising storing a first state of the shift register of the first n-state shift register of the first decoder when corresponding symbols in the first coded sequences and the second sequence indicate an error, and correcting up to k symbols in error in the first decoded sequence by processing the first state and the start state by the processor.

In accordance with yet a further aspect of the present invention a system is provided, wherein an n-state symbol is represented by an n-state signal able to assume one of n states.

In accordance with yet a further aspect of the present invention a system is provided, wherein an n-state symbol is represented by a binary word, and a decoder is implemented by using binary circuitry.

In accordance with yet a further aspect of the present invention a system is provided, wherein n=2^{q} with q and integer equal to 1 or greater than 1.

In accordance with yet a further aspect of the present invention a system is provided, wherein the system is part of a communication system.

In accordance with yet a further aspect of the present invention a system is provided, wherein the system is part of a cellular telephone system.

In accordance with yet a further aspect of the present invention a system is provided, wherein the system is applied in a data storage system.

### DESCRIPTION OF THE DRAWINGS

FIG. 1 is a diagram of an n-state convolutional coder in accordance with an aspect of the present invention;

FIG. 2 is a diagram of an n-state convolutional decoder in accordance with an aspect of the present invention;

FIG. 3 is a diagram of a binary convolutional decoder in accordance with an aspect of the present invention;

FIGS. 4-8 provide diagrams of one or more binary convolutional decoders in accordance with an aspect of the present invention;

FIG. 9 provides a diagram of an implementation of a decoder in accordance with an aspect of the present invention;

FIG. 10 is a diagram of a convolutional coder in accordance with an aspect of the present invention;

FIG. 11 is a diagram of a convolutional decoder in accordance with an aspect of the present invention;

FIG. 12 is a diagram of a convolutional coder in accordance with an aspect of the present invention;

FIG. 13 is a diagram of a convolutional decoder in accordance with an aspect of the present invention;

FIG. 14 is a diagram of a convolutional coder in accordance with an aspect of the present invention;

FIG. 15 is a diagram of a convolutional decoder in accordance with an aspect of the present invention;

FIG. 16 is a diagram of a convolutional coder in accordance with an aspect of the present invention;

FIG. 17 is a diagram of a convolutional decoder in accordance with an aspect of the present invention;

FIG. 18 is a flow diagram of a decoding method in accordance with an aspect of the present invention;

FIG. 19 is a diagram of a convolutional coder in accordance with an aspect of the present invention;

FIG. 20 is a diagram of a convolutional decoder in accordance with an aspect of the present invention;

FIG. 21-23 are diagrams of convolutional decoders in accordance with an aspect of the present invention; and

FIGS. 24-26 are diagrams of systems in accordance with an aspect of the present invention.

### DETAILED DESCRIPTION OF THE INVENTION

Standard binary LFSR based scramblers, descramblers and sequence generators are generally provided in Fibonacci form. The inventor has shown elsewhere, such as in U.S. Non-Provisional patent application Ser. No. 10/935,960 filed on Sep. 8, 2004 now U.S. Pat. No. 7,643,632 issued on Jan. 5, 2010, entitled: Ternary and multi-value digital signal scramblers, descramblers and sequence generators, which is incorporated hereby in its entirety by reference, how non-binary scramblers, descramblers and sequence generators can be created in Fibonacci form.

The inventor has also shown in U.S. Pat. No. 7,487,194 issued on Feb. 3, 2009, which is incorporated herein by reference, how one can create LFSR based scramblers and descramblers in Galois configuration, including n-state LFSR based scramblers, descramblers in Galois configuration. Galois LFSRs with multiple taps have an inherent advantage over Fibonacci LFSRs, as they process all symbols in one clock-cycle. In Fibonacci LFSRs one has to wait until all functions in a feedback loop have been executed.

In clock constrained circuits, it is advantageous to apply Galois based LFSRs.

A convolutional coder as traditionally known, uses at least two LFSR based coders which may be considered two LFSR based descramblers. This allows at the receiving side an opportunity to at least detect errors is two sequences of symbols generated by these coders from the same initial sequence of symbols. A symbol herein for now is one that can assume one of 2 or more states. Later on the analysis will be extended to symbols having one of 3 or more states.

One underlying principle of the error correcting capabilities of coding a sequence of symbols by at least one LFSR based coder and having either a second sequence being uncoded or also coded but by a different LFSR based coder is that one may compare both sequences and determine, either in a probabilistic way or in a deterministic way how one may arrive at a certain stage of a coded sequence. Probabilistic decoders of convolutional codes use a trellis and the known Viterbi decoding approach.

The inventor has shown in the earlier recited patent application that one may determine a state of a shift register, and use the content of the shift register as the correct symbols in a deterministic way. Such a method does not require a predetermined initial state of the LFSRs.

As an aspect of the present invention, one may create at least one coded sequence with a coder in Galois LFSR and at least one sequence either coded by another LFSR based coder or the other sequence being an uncoded sequence.

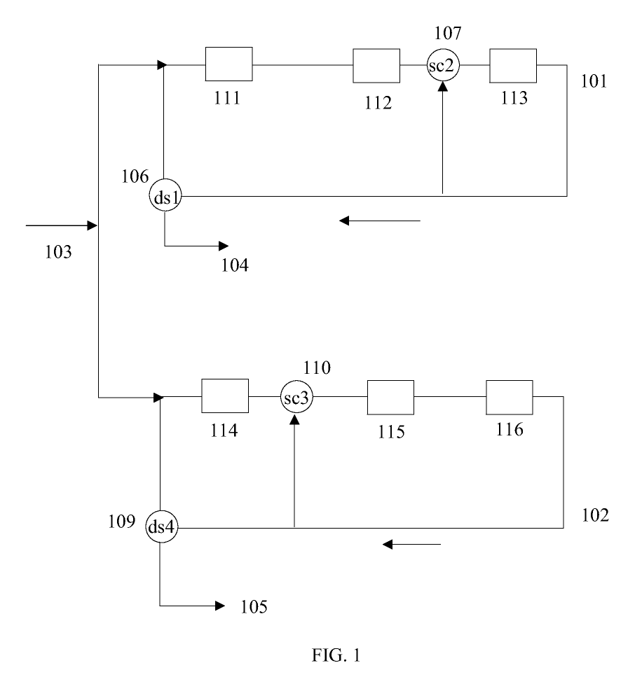

FIG. 1 shows in diagram an illustrative example of a dual n-state LFSR based coder in Galois configuration. In this illustrative example it has a first coder 101 and a second coder 102, each having an LFSR in Galois configuration, the LFSRs having 3 shift register elements. Coder 101 has shift register elements 111, 112 and 113 with 1 tap to a device 107 implementing logic function sc2. The coders are in a descrambler configuration with 101 having a descrambling device 106, implementing a logic function ds1. The device 106 has on one input an output of the LFSR being the feedback loop. The second input of 106 is connected to input 103 to receive a to be coded sequence of n-valued symbols, each symbol able to assume one of n states, with n≧2. One may insert n-valued inverters into any connection of the LFSR or to any input of a logic device. One may also reduce any n-valued logic function with an inverter on an input to a new function whereby the inverter is moved into the function. This aspect is explained by the inventor in U.S. Non-Provisional patent application Ser. No. 10/935,960, filed on Sep. 8, 2004, entitled TERNARY AND MULTI-VALUE DIGITAL SCRAMBLERS, DESCRAMBLERS AND SEQUENCE GENERATORS, which is incorporated herein by reference.

Coder 102 also has three shift register elements now with numerals 114, 115 and 116. The LFSR of 102 is different from the one of 101. There is one feedback tap to a device 110 implementing an n-valued logic function sc3. Coder 102 has a device 109 implementing an n-valued logic function ds4. One input of device 109 is connected to 103 to receive the same sequence as coder 101. Coder 101 provides a coded sequence on output 104 and coder 102 provides a coded sequence on 105.

Not showing but assumed is a clock signal that controls the LFSRs and the shifting speed, which is synchronized with the sequence provided on 103. Accordingly, when p symbols are inputted on 103 then p coded or scrambled symbols are outputted on 104 and 105 each.

The n-state LFSR can be implemented in many different ways. In a first embodiment it is implemented as a shift register of which each element can hold and shift one n-state symbol. In a further embodiment a single n-state symbol is represented by a single signal. All elements in the LFSR are enabled to process, to hold or to shift such a signal. In a further embodiment a single n-state symbol is represented by a plurality of signals. For instance a 256-state symbol may be represented by 8 bits. Each shift register element and each function is enabled to process in a synchronized fashion each symbol as a plurality of signals. For instance, a 256-state symbol is represented as a word of 8-bits. In such an embodiment a shift register element can hold 8 bits. A function sc2 implemented by device 107 may be implemented by 8 binary XOR functions. An LFSR can be implemented by an addressable memory. An LFSR can also be implemented as an expression in for instance a Digital Signal Processor (DSP) that calculates the individual states of the n-state LFSR.

This aspect of any n-state LFSR state to be calculated by an expression rather than being generated by a true or simulated shift register may be novel. The following will explain in detail how one can determine such expressions. Expressions are used to calculate for instance initial or starting states of an LFSR. It is to be understood that an n-state LFSR may exist as a true LFSR, as a simulated LFSR for instance with stored LFSR states in an addressable memory, or as expressions that can be evaluated and that are associated with a certain moment of state in the operation of an LFSR. Accordingly, an implementation of an LFSR herein includes all its embodiments that enables a machine to determine any state of the LFSR as if it was an LFSR containing a shift register, a feed-back connection, any n-state logic function or n-state inverter, and input and output to respectively receive and provide a symbol or a signal representing a symbol.

Furthermore, an LFSR or an implementation thereof is assumed to synchronize its internal states for instance by way of a clock signal. Even if such a clock cycle is not shown or mentioned, it may be assumed to be present.

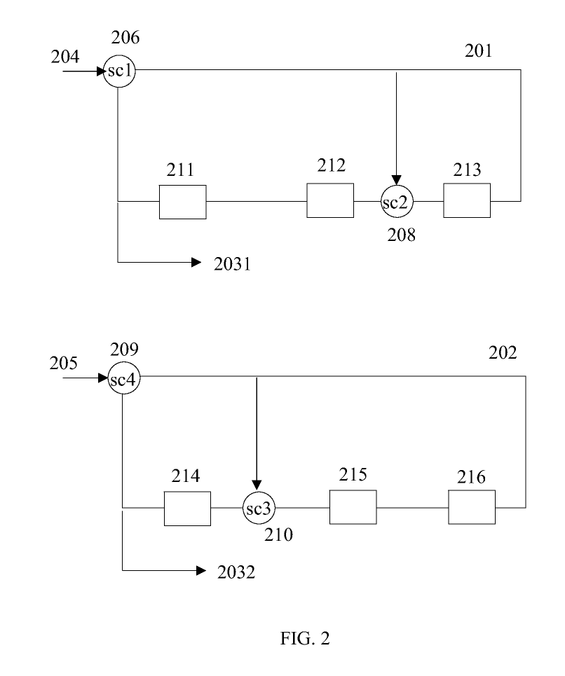

The corresponding decoders of the coders of FIG. 1 are shown in FIG. 2. The corresponding decoder of coder 101 is decoder 201 with the symbols of output 104 provided on input 204. The LFSR has shift register elements 211, 212 and 213 and feedback taps to device 208 implementing function sc2. The decoder 201 has also a device 206 which implements a functions sc1 which reverses function sc1. The device 206 has output 2031 which provides under the right conditions the original symbols that were entered on 103.

Coder 202 receives the scrambled symbols of coder 102 on input 205. The LFSR has the shift register elements 214, 215 and 216 and the single tap to device 210 implementing logic function sc3. The decoder also has a device 209 which may be called a descrambling device which implements function sc4 which reverses function ds4. Device 209 provides on output 2032 under the right conditions the original symbols that were entered on 103.

If there are no errors in the scrambled sequences and the initial state of a descrambler corresponds with the initial state of the corresponding scrambler, then both descramblers will generate identical sequences which correspond to the original sequence that was provided on input 103. As soon as the sequences generated on 2031 and 2032 are different, one may assume that an error has occurred in one of the scrambled sequences that were provided on 204 and 205.

Because the decoders 201 and 202 are not self-synchronizing and perpetuate errors, it is not clear when the two sequences inputted on 204 and 205 are error-free again.

As a first step one may initiate the coders 101 and 102 with a certain content of the shift register. One then enters a sequence of symbols on 103 and two sequences will be generated: one on output 104 and one on output 105. The decoders 201 and 202 are initiated with the same shift register content as their corresponding coders. The two coded sequences are received on 204 and 205. If no errors have occurred in the coded sequences, then 2031 and 2032 generate identical sequences, which are identical to the original sequence on 103.

When an error has occurred in one or both of the coded sequences and a symbol has changed in state, the sequences outputted on 2031 and 2032 may be different.

Because of the single or multiple errors in the input sequences the output sequences on 2031 and 2032 probably are different. The errors will be shifted through the shift register and are ultimately fed back into the shift register. The errors are perpetuated and the two output sequences of the decoder will largely be different, even when the input sequences have no further errors. One has to reset the content of the shift registers to correctly decode.

A method will be provided to reset the content of the shift registers. A condition for the reset is that at least twice the number of shift register element symbols (in the example of FIG. 2: 2 times 3=6) in the output sequence may be assumed to originate from correct input sequences.

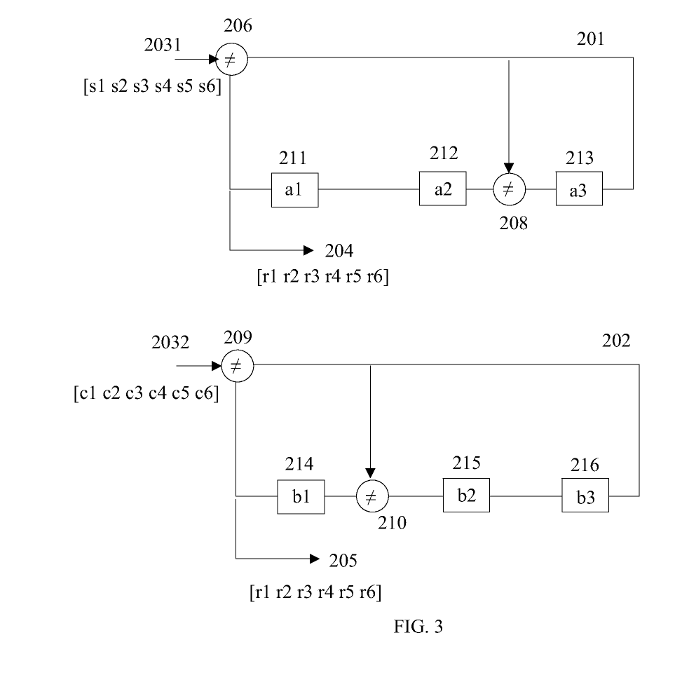

FIG. 3 shows the binary case for the coders of FIG. 2. The structure and components in FIG. 3 are the same as in FIG. 1. However, in FIG. 3 all shift register elements are binary and all functions are the binary XOR function. Furthermore, in coder 201 the input 204 is provided with the coded sequence [s1 s2 s3 s4 s5 s6], the initial state of the shift register is [a1 a2 a3] and the output generates [r1 r2 r3 r4 r5 r6]. Coder 202 is provided with [c1 c2 c3 c4 c5 c6] and the initial state of the coder is [b1 b2 b3]. The input sequences are assumed to be error free, and output 205 sequence is also [r1 r2 r3 r4 r5 r6]. One wants to determine the initial state of the shift registers to make sure that 201 and 202 both generate the same sequence [r1 r2 r3 r4 r5 r6].

One may create a switching table for binary decoder 201 describing the states of the shift register elements sr1, sr2 and sr3 and the generated output, based on the initial state of the shift registers [a1 a2 a3] and the input sequence [s1 s2 s3 s4 s5 s6].

| input | output | sr1 | sr2 | sr3 |
|---|---|---|---|---|
| | | a1 | a2 | a3 |
| s1 | s1 ≠ a3 | s1 ≠ a3 | a1 | a2 ≠ a3 |
| s2 | s2 ≠ a2 ≠ a3 | s2 ≠ a2 ≠ a3 | s1 ≠ a3 | a1 ≠ a2 ≠ a3 |
| s3 | s3 ≠ a1 ≠ a2 ≠ a3 | s3 ≠ a1 ≠ a2 ≠ a3 | s2 ≠ a2 ≠ a3 | s1 ≠ a1 ≠ a2 |
| s4 | s4 ≠ s1 ≠ a1 ≠ a2 | s4 ≠ s1 ≠ a1 ≠ a2 | s3 ≠ a1 ≠ a2 ≠ a3 | s1 ≠ s2 ≠ a1 ≠ a3 |
| s5 | s5 ≠ s1 ≠ s2 ≠ a1 ≠ a3 | s5 ≠ s1 ≠ s2 ≠ a1 ≠ a3 | s4 ≠ s1 ≠ a1 ≠ a2 | s1 ≠ s2 ≠ s3 ≠ a2 |
| s6 | s6 ≠ s1 ≠ s2 ≠ s3 ≠ a2 | s6 ≠ s1 ≠ s2 ≠ s3 ≠ a2 | s5 ≠ s1 ≠ s2 ≠ a1 ≠ a3 | s2 ≠ s3 ≠ s4 ≠ a1 |

One can see that all states depend upon a1, a2, a3 and s1, s2, s3, s4, s5 and s6.

One may create a similar switching table for binary decoder 202, using initial states [b1 b2 b3] and input sequence [c1 c2 c3 c4 c5 c6].

| input | output | sr1 | sr2 | sr3 |
|---|---|---|---|---|
| | | b1 | b2 | b3 |
| c1 | c1 ≠ b3 | c1 ≠ b3 | b1 ≠ b3 | b2 |
| c2 | c2 ≠ b2 | c2 ≠ b2 | c1 ≠ b2 ≠ b3 | b1 ≠ b3 |
| c3 | c3 ≠ b1 ≠ b3 | c3 ≠ b1 ≠ b3 | c2 ≠ b1 ≠ b2 ≠ b3 | c1 ≠ b2 ≠ b3 |
| c4 | c4 ≠ c1 ≠ b2 ≠ b3 | c4 ≠ c1 ≠ b2 ≠ b3 | c3 ≠ c1 ≠ b1 ≠ b2 | c2 ≠ b1 ≠ b2 ≠ b3 |
| c5 | c5 ≠ c2 ≠ b1 ≠ b2 ≠ b3 | c5 ≠ c2 ≠ b1 ≠ b2 ≠ b3 | c4 ≠ c2 ≠ c1 ≠ b1 | c3 ≠ c1 ≠ b1 ≠ b2 |
| c6 | c6 ≠ c3 ≠ c1 ≠ b1 ≠ b2 | c6 ≠ c3 ≠ c1 ≠ b1 ≠ b2 | c5 ≠ c3 ≠ c2 ≠ c1 ≠ b3 | c4 ≠ c2 ≠ c1 ≠ b1 |

If all initial states are correct and there are no errors in either [s1 s2 s3 s4 s5 s6] or in [c1 c2 c3 c4 c5 c6] then the output sequences [r1 r2 r3 r4 r5 r6] of both decoders should be identical. Based on that requirement one can now create 6 equations with six unknowns:

The functions used in this binary example are all XOR functions. One may also use one or more EQUIVALENCE or ‘=’ functions.

| a1 | a2 | a3 | b1 | b2 | b3 | s | or | c | | | | |
|---|---|---|---|---|---|---|---|---|---|---|---|---|
| 0 | 0 | 1 | 0 | 0 | 1 | s1 | c1 | | | | | |
| 0 | 1 | 1 | 0 | 1 | 0 | s2 | c2 | | | | | |
| 1 | 1 | 1 | 1 | 0 | 1 | s3 | c3 | | | | | |
| 1 | 1 | 0 | 0 | 1 | 1 | s1 | s4 | c1 | c4 | | | |
| 1 | 0 | 1 | 1 | 1 | 1 | s1 | s2 | s5 | | c2 | c5 | |
| 0 | 1 | 0 | 1 | 1 | 0 | s1 | s2 | s3 | s6 | c1 | c3 | c6 |

There are now 6 binary equations with six unknowns and 12 known entities, as [s1 s2 s3 s4 s5 s6] and [c1 c2 c3 c4 c5 c6] were assumed to be error free.

One may solve the equations by using a modified Cramer's rule for the binary case, wherein multiplying is the binary AND function and the addition is the XOR function. One may also solve the equation by substitution. In the end one can find an expression that determines a1, a2, a3, b1, b2 and b3 each as a function of [s1 s2 s3 s4 s5 s6] and [c1 c2 c3 c4 c5 c6].

A modified Cramer's rule for binary equations will be illustrated with the following example. Assume the following three binary equations:

x1+x2=0

x1+x3=1

x1+x2+x3=0

Herein ‘+’ is mod-2 add and * is the binary AND function.

The determinant of the coefficients of the unknowns x1, x2 and x3 is

$$D = \vert \begin{matrix}1 & 1 & 0 \\ 1 & 0 & 1 \\ 1 & 1 & 1\end{matrix} \vert = 1 * \vert \begin{matrix}0 & 1 \\ 1 & 1\end{matrix} \vert + 1 * \vert \begin{matrix}1 & 1 \\ 1 & 1\end{matrix} \vert + 0 * \vert \begin{matrix}1 & 0 \\ 1 & 1\end{matrix} \vert \\ = 1 * ( 0 + 1 ) + 1 * ( 1 + 1 ) + 0 = 1 * 1 + 1 * 0 + 0 = 1.$$

The solution vector is

$$d = \vert \begin{matrix}0 \\ 1 \\ 0\end{matrix} \vert .$$

The solutions are:

$$x 1 = \frac{\vert \begin{matrix}0 & 1 & 0 \\ 1 & 0 & 1 \\ 0 & 1 & 1\end{matrix} \vert}{D} = \frac{1 * ( 1 * 1 + 1 * 0 ) + 0 + 0}{1} = 1.$$

$$x 2 = \frac{\vert \begin{matrix}1 & 0 & 0 \\ 1 & 1 & 1 \\ 1 & 0 & 1\end{matrix} \vert}{D} = \frac{1 * ( 1 * 1 + 1 * 0 ) + 0 + 0}{1} = 1.$$

$$x 3 = \frac{\vert \begin{matrix}1 & 1 & 0 \\ 1 & 0 & 1 \\ 1 & 1 & 0\end{matrix} \vert}{D} = \frac{1 * ( 0 * 0 + 1 * 1 ) + 1 * ( 1 * 0 + 1 * 1 ) + 0}{1} = 0.$$

One should keep in mind that ‘−’ is the same as ‘+’.

The Cramers' rule has been applied to fully explain the process of solving the equations. One may also apply more efficient algorithms for solving linear equations such as the Gaussian elimination, which usually provides a faster result.

In one illustrative example one may run coders 101 and 102 being the binary corresponding coders for the decoders of FIG. 3 for 14 cycles, with coder 101 having initial state [0 1 0] and coder 102 having initial state [1 1 1]. The input sequence of 14 binary signals on 103 is [1 0 1 1 0 0 1 1 0 0 0 1 1 1]. Coder 101 generates [1 1 0 1 0 1 1 1 0 1 0 1 1 1] on 104 and coder 102 generates [0 1 1 1 0 1 0 0 1 0 0 1 1 1].

One may run the above equations for 6 corresponding output symbols on outputs 104 and 105. For instance one may assume that all symbols are correct, and use the first six symbols outputted on 104 and the first six symbols outputted on 105 for solving the equations. This will generate [a1 a2 a3]=[0 1 0] and [b1 b2 b3]=[1 1 1], which is of course correct. One may then initialize the binary decoders 201 and 202 with these states and input the decoders with the appropriate coded sequences to generate the correctly decoded sequences. One should run 2 decoders 201 and 202 to determine when again an error occurs. However, for correctly decoding only one decoder is required when one is certain that no errors have occurred.

One may also correct in this example up to 3 errors in a decoded sequence, due to errors in the coded sequences. In coders and decoders with n shift register elements in Galois configuration, one may correct up to n errors in a decoded sequence.

Furthermore, one can always correct 2 errors in the provided example. This is because the calculated state of the decoder contains unmodified earlier generated correct symbols. For instance in FIG. 3, decoder 201, the initial states a1 and a2 represent the two earlier generated decoded symbols. Because the state [a1 a2 a3] is assumed to be correct, then a1 and a2 represent earlier correctly decoded symbols. Herein a1 represents the symbol just before r1, and a2 represents the symbol generated 2 symbols before that. Accordingly a sequence decoded as [r0 er1 er2 er3 s1 s2 s3 s4 s5 s6] wherein er1, er2 and er3 are symbols in error can be corrected as being [r0 er1 a2 a1 s1 s2 s3 s4 s5 s6]. This has been demonstrated for the binary case. It also applies to any n-valued case.

One may check if the assumption that the incoming sequences are error free is correct by using the calculated initial states and decoding the incoming sequences. Clearly the first six generated decoded symbols will be correct, as this was the condition for the calculation. If the seventh and later symbols are also correct, one may assume that the assumption was correct. It may of course be the case that the assumption was correct and that the 7^{th} decoded symbol is in error again because the related coded symbols were in error. Accordingly, one should design the coders and decoders with the error performance of the transmission channel in mind.

As was shown above decoded symbols [a2 a1] in the decoded symbols can be determined directly from calculating a correct content of the shift register [a1 a2 a3]. If one is sure that no more errors have occurred in a decoded sequence than the number of shift register elements, one can correct up to n errors by a process in accordance with a further embodiment of the present invention that may be called bridging.

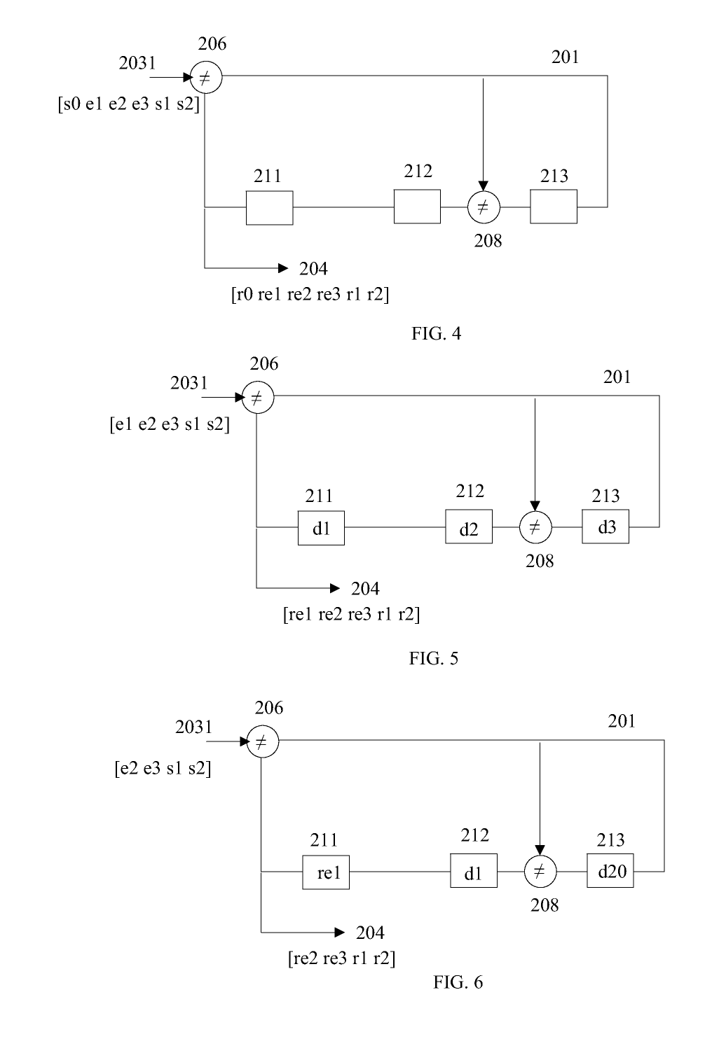

The solving of errors by bridging is illustrated in FIGS. 4-8. In FIG. 4 the input 2031 is provided with the last correct symbol s0 before errors e1, e2 and e3 are entered. The output 204 provides the last correctly decoded symbol r0, before it generates errors. One may say that over 10 clock cycles the sequence [s0 e1 e2 e3 s1 s2 s3 s4 s5 s6] is entered on 2031, while 204 provides the decoded sequence [r0 re1 re2 re3 r1 r2 r4 r5 r6] as a result of this inputted sequence. It was shown above that one may calculate the states of the shift register at the beginning of a series of error free symbols, starting with s1. Clearly, when e1, e2 and e3 are entered also symbols in error may be generated.

FIG. 5 illustrates what happens when the first error is entered at input 2031. At that stage no errors have been entered into the shift register, and one may record the state of the shift register at that moment being [d1 d2 d3]. FIG. 6 illustrates the status at the next clock cycle. The symbol in error re1 that was generated is entered into the shift register, and everything has shifted to the right. The content of the shift register is now [re1 d1 d20]. Herein d20 is generated by d2≠d3 in the previous cycle.

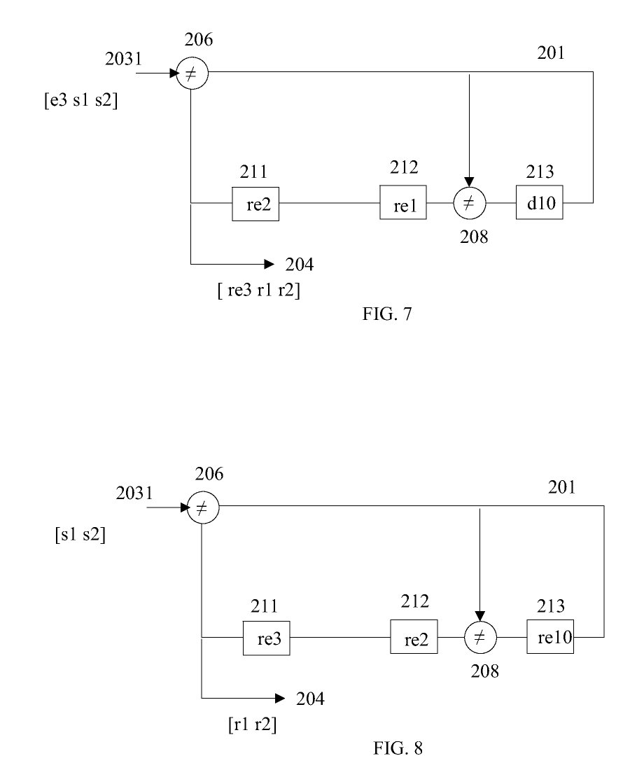

FIG. 7 shows the next cycle, with re3 being generated and re2 entered into the shift register, with the shift register state being [re2 re1≠d10], wherein d10 is generated by d1≠d20 or d1≠d2≠d3.

FIG. 8 shows the stage wherein s1 is entered at 2031 and the content of the shift register is [re3 re2 re10] with re10 being generated by re1≠d10 or re1≠d1≠d2≠d3. However, at this stage the content of the shift register is also [a1 a2 a3] as was calculated above. Accordingly, re3=a1, re2=a2 and re1≠d1≠d2≠d3=a3 or re1=d1≠d2≠d3≠a3.

The above has demonstrated how one can use a convolutional coder in Galois configuration, using at least two coders with k shift register elements; restarting correct decoding and error correcting at least p symbols if at least one LFSR has its first tap after p shift register elements, wherein the most left shift register element is the first one. It should be clear that one may express these conditions in a polynomial form.

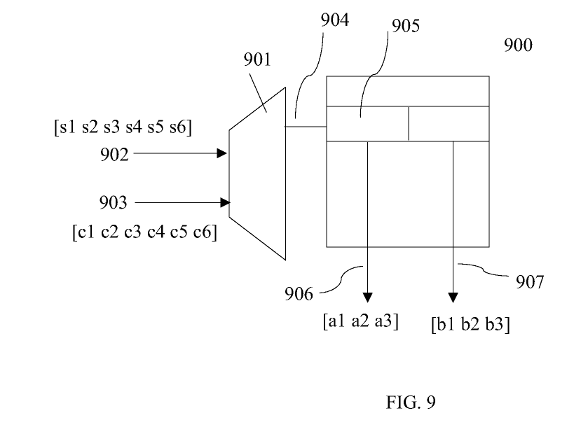

One may express the solution for Cramer's rule in a combinational circuit. However, this will require switching cycles, which may be counter productive to the speed of error correction. One may solve all six equations, certainly if it is necessary to use initial states of the LFSR to determine if the decoding will be error free. Otherwise, it may suffice to determine for instance only [a1 a2 a3]. In a further embodiment of the present invention one may determine all possible occurrences of [s1 s2 s3 s4 s5 s6] and [c1 c2 c3 c4 c5 c6] and their related solutions of [a1 a2 a3] and [b1 b2 b3] and store those in a memory. This is illustrated in FIG. 9 which shows an addressable memory 900. Also shown is an address generator 901 which has as input 902, which may be 6 parallel inputs providing s1, s2, s3, s4, s5 and s6 in a parallel fashion, and input 903 which may be 6 parallel inputs providing c1, c2, c3, c4, c5 and c6 in a parallel fashion. Address generator 901 uses the inputted coded symbols generated by coders 101 and 102 to create an address that enables an address line 904. The enabled address line selects for reading a memory content 905 which is provided on out 906 and 907, which may both be 3 parallel outputs, to provide [a1 a2 a3] and [b1 b2 b3].

One may also apply an addressable memory to execute the bridging for error correcting, using the calculated states [a1 a2 a3] for instance and a last known correct LFSR state [d1 d2 d3] as inputs. In a further embodiment one may determine error corrected symbols with combinational circuitry. In yet a further embodiment one may also create an address for an addressable memory from the ‘assumed’ to be correct coded symbols and a last known or assumed to be correct LFSR state to create as an output the calculated states of restart for the decoders and the error corrected symbols.

Using a memory, rather than a combinational circuit may greatly speed up generating the initial LFSR content. Especially in rather small binary LFSRs the memory does not need to be large. With a 12 bits input only 4 k memory is required. One may actually also implement the Galois LFSR in an addressable memory. The inventor has shown in U.S. patent application Ser. No. 11/534,837 filed on Sep. 25, 2006, and U.S. patent application Ser. No. 11/555,730 filed on Nov. 2, 2006, which are both incorporated herein by reference in their entirety, how one may implement LFSRs in addressable memory. Accordingly, one can execute the error correcting decoding very rapidly.

A condition for the above method to work is that Cramer's rule has to generate a determinant which is related to a set of independent equations, in the above example of 6 independent equations. This may mean that not all tap configurations in the Galois LFSR will work, but that have to be limited by LFSRs that can be expressed as irreducible polynomials of degree m, wherein m is the length of the shift register.

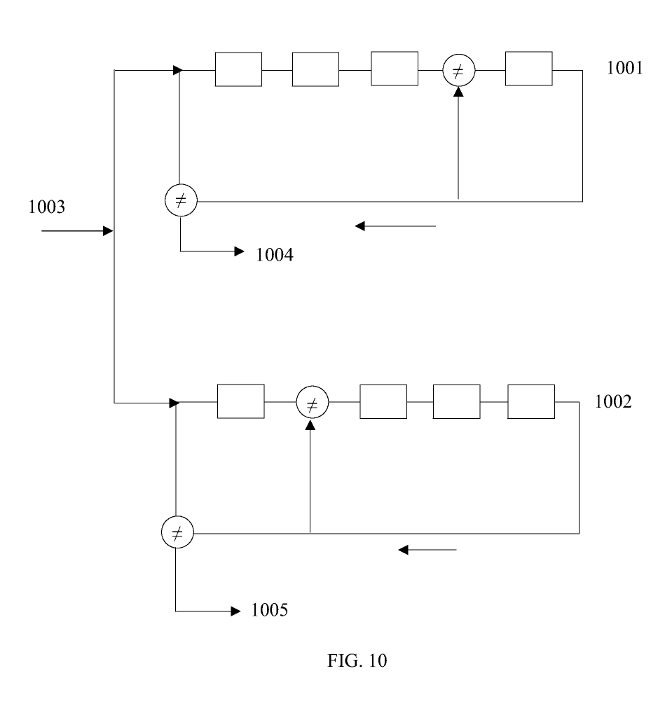

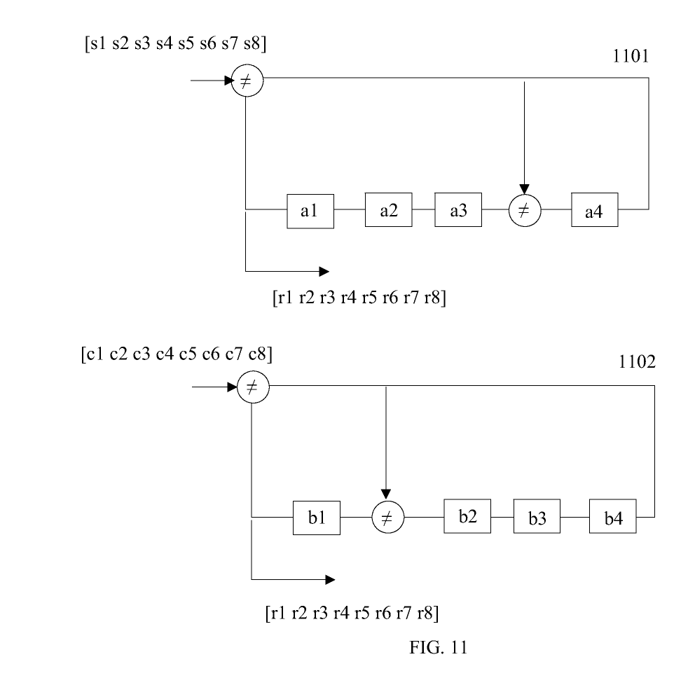

As a further example in FIG. 10 a coder is provided somewhat like the coder of FIG. 1, with all components being binary, including the binary XOR functions in coders 1001 and 1002. However, the LFSRs now have 4 shift register elements. A diagram of the related decoders 1101 and 1102 is provided in FIG. 11 with initial shift register states [a1 a2 a3 a4] and [b1 b2 b3 b4] respectively.

The approach to determine an initial state is as before. Only, one requires at least 8 symbols to be error free after restart of correct decoding for determining an initial restart position of the LFSRs. The table that determines the equations to solve initial states [a1 a2 a3 a4] and [b1 b2 b3 b4] of decoders is provided below.

| a1 | a2 | a3 | a4 | b1 | b2 | b3 | b4 | s | or | c | | | | | |
|---|---|---|---|---|---|---|---|---|---|---|---|---|---|---|---|
| 0 | 0 | 1 | 1 | 0 | 0 | 0 | 1 | s1 | | | | | c1 | | |
| 0 | 0 | 1 | 1 | 0 | 0 | 1 | 0 | s2 | | | | | c2 | | |
| 0 | 1 | 1 | 1 | 0 | 1 | 0 | 0 | s3 | | | | | c3 | | |
| 1 | 1 | 1 | 1 | 1 | 0 | 0 | 1 | s4 | | | | | c4 | | |
| 1 | 1 | 1 | 0 | 0 | 0 | 1 | 1 | s1 | s5 | | | | c1 | c5 | |
| 1 | 1 | 0 | 1 | 0 | 1 | 1 | 0 | s1 | s2 | s6 | | | c2 | c6 | |
| 1 | 0 | 1 | 0 | 1 | 1 | 0 | 1 | s1 | s2 | s3 | s7 | | c3 | c7 | |
| 0 | 1 | 0 | 1 | 1 | 0 | 1 | 0 | s1 | s2 | s3 | s4 | s8 | c1 | c4 | c8 |

One may apply Cramer's rule to solve the equations for error-free coded sequences [s1 s2 s3 s4 s5 s6 s7 s8] and [c1 c2 c3 c4 c5 c6 c7 c8] to determine [a1 a2 a3 a4] and [b1 b2 b3 b4].

A to be coded sequence xin=[1 0 1 1 0 0 1 1 0 0 0 1 1 1] provided on 1003 will be coded by coder 1001 into [1 0 0 0 0 0 0 1 0 0 1 1 1 1] and provided on 1004 with the initial state of the LFSR of 1001 being [0 1 0 0]. Coder 1002 will generate on 1005 sequence [0 1 1 1 0 0 0 0 0 1 0 0 0 1] when the initial state of the LFSR of 1002 is [1 0 1 1]. One may apply the above tables and the modified binary Cramer's rule to determine the starting state of the LFSRs. One may also error-correct up to 4 symbols using the earlier explained bridging approach. While it is fairly easy to calculate the solutions, it can be seen that more calculations have to be performed than with the 3 elements LFSRs. So, as the shift registers get longer, it may be beneficial to generate the solutions by using the earlier described memory based solution retrieval.

Non-binary error-correcting coders and decoders

Illustrative examples have been provided for binary coders and decoders, using binary shift registers and binary logic functions. While the binary logic function XOR has been used for illustrative purposes, one may also apply one or more EQUIVALENCE functions. In a further embodiment, one may use n-valued LFSRs, wherein the shift register elements can receive, store and output an n-valued symbol. In a first embodiment an n-valued symbol is a single symbol that can assume one of n states with n an integer being greater than 2. In a further embodiment an n-valued symbol is a single symbol that can assume one of n states with n an integer being equal to 2 or greater than 2. In yet a further embodiment, a single n-valued symbol is represented by a single signal having one of n states. Such a signal state can be represented by an amplitude, phase, frequency, or wavelength of the signal, or by any other property that can assume one of n states. In a further embodiment an n-valued symbol may be represented by two or more p-valued symbols with p<n. For instance an 8-valued signal may be represented in one embodiment by three binary signals.

An n-valued LFSR and encoder or decoder further may have n-valued or n-state switching functions. An n-state switching function may have at least a first and a second input and an output, and the relation between inputs and output is determined by at least a 2 by 2 truth table. An n-valued logic function may be implemented in n-state device, for instance as disclosed by the inventor in U.S. Pat. No. 7,355,444 issued on Apr. 8, 2008 and U.S. Pat. No. 7,218,144 issued on May 15, 2007 which are both incorporated herein by reference in their entirety. One may also implement an n-valued logic function in a binary device. When true n-state signals have to be processed, one may apply binary devices with an A/D converter at an input and a D/A converter at an output.

The following n-state examples will use 8-state or 8-valued logic functions. In particular 8-state self reversing, commutative and associative logic functions will be applied. If one does not use n-valued multipliers or n-state inverters, the approach is not unlike the binary approach. It is noted that the approach provided herein applies to any n-valued coder/decoder using reversible n-valued logic functions, including 3-valued, 4-valued or any n-valued coder/decoder. For practical purposes an 8-valued example is provided. However, much higher valued approaches such as a 256-valued coder/decoder are fully contemplated. In some cases the n-valued logic functions may not be associative. This may complicate somewhat the creation of equations to find initial LFSR states.

The truth table of the 8-valued self-reversing, commutative and associative switching function sc8 is provided in the following table.

| sc8 | 0 | 1 | 2 | 3 | 4 | 5 | 6 | 7 |
|---|---|---|---|---|---|---|---|---|
| 0 | 0 | 1 | 2 | 3 | 4 | 5 | 6 | 7 |
| 1 | 1 | 0 | 4 | 7 | 2 | 6 | 5 | 3 |
| 2 | 2 | 4 | 0 | 5 | 1 | 3 | 7 | 6 |
| 3 | 3 | 7 | 5 | 0 | 6 | 2 | 4 | 1 |
| 4 | 4 | 2 | 1 | 6 | 0 | 7 | 3 | 5 |
| 5 | 5 | 6 | 3 | 2 | 7 | 0 | 1 | 4 |
| 6 | 6 | 5 | 7 | 4 | 3 | 1 | 0 | 2 |
| 7 | 7 | 3 | 6 | 1 | 5 | 4 | 2 | 0 |

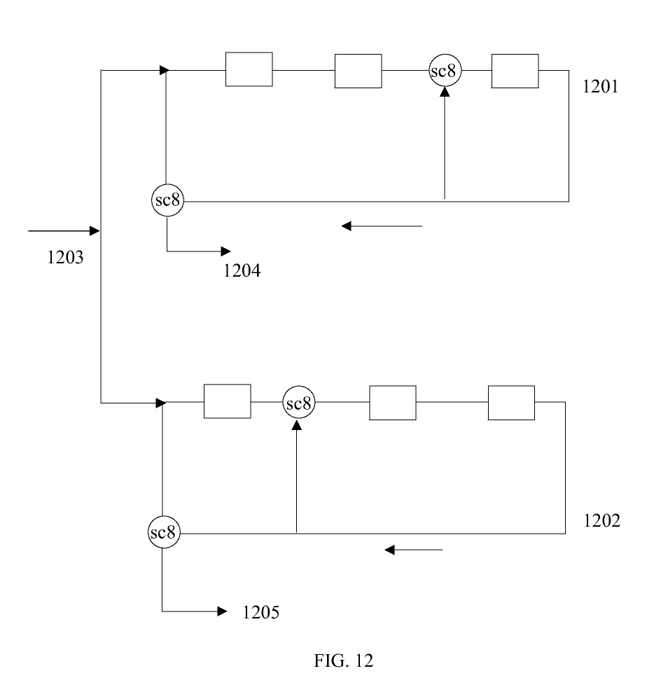

FIG. 12 shows a diagram of an 8-valued coder using 8-valued shift registers for coders 1201 and 1202, and implementing an 8-valued logic function sc8. A sequence of 8-valued symbols is provided on 1203 and outputs 1204 and 1205 each provides a coded sequence of 8-valued symbols.

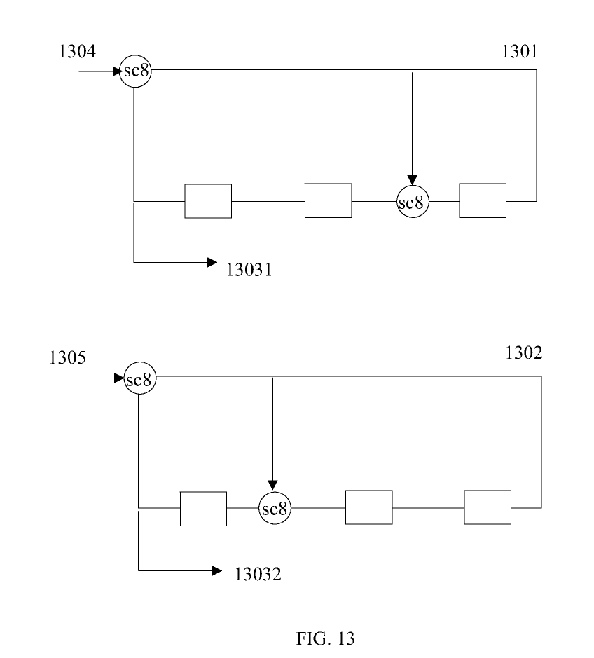

The corresponding decoders 1301 and 1302 are shown in FIG. 13. The sequence generated on 1204 is entered on 1304 and the sequence that was generated on 1205 is entered on 1305. Under the right conditions the sequences generated on 13031 and 13032 will be identical. The solution table is the same as used for the binary case related to FIG. 3 with as two differences that the XOR is replaced by sc8 and the binary multiplication AND is replaced by the 8-valued function MUL8. The truth table for MUL8 is provided below.

| MUL8 | 0 | 1 | 2 | 3 | 4 | 5 | 6 | 7 |
|---|---|---|---|---|---|---|---|---|
| 0 | 0 | 0 | 0 | 0 | 0 | 0 | 0 | 0 |
| 1 | 0 | 1 | 2 | 3 | 4 | 5 | 6 | 7 |
| 2 | 0 | 2 | 3 | 4 | 5 | 6 | 7 | 1 |
| 3 | 0 | 3 | 4 | 5 | 6 | 7 | 1 | 2 |
| 4 | 0 | 4 | 5 | 6 | 7 | 1 | 2 | 3 |
| 5 | 0 | 5 | 6 | 7 | 1 | 2 | 3 | 4 |
| 6 | 0 | 6 | 7 | 1 | 2 | 3 | 4 | 5 |
| 7 | 0 | 7 | 1 | 2 | 3 | 4 | 5 | 6 |

One may recognize that sc8 and MUL8 are addition and multiplication over Galois Field GF(2³). One may then adjust Cramer's rule for this 8-valued case by using as ‘+’ the function ‘sc8 ’ and as multiplication * the function ‘MUL8’.

A determinant |D| which may contain terms formed for instance of a11*a22*a33*a44*a55*a66+a12*a21*a34*a43*a56*a65+etc may then be calculated by using the above definitions of ‘+’ and ‘*’. Dividing by a number in this instance is the same as multiplying with the reverse. One may check for instance that dividing by 3 is the same as multiplying by 6.

The 8-valued sequence [1 0 1 1 2 3 1 1 6 0 4 1 1 7] inputted on 1203 will generate [6 7 0 1 2 7 1 4 1 6 7 0 0 6] on 1204 and [2 5 7 5 5 2 3 7 5 7 4 4 1 3] on 1205 when the initial states are [a1 a2 a3]=[3 4 5] and [b1 b2 b3]=[6 5 4].

One may determine the different initial states as was shown before and also correct up to three symbols in error in the decoded sequence based on the calculated initial state of the LFSRs.

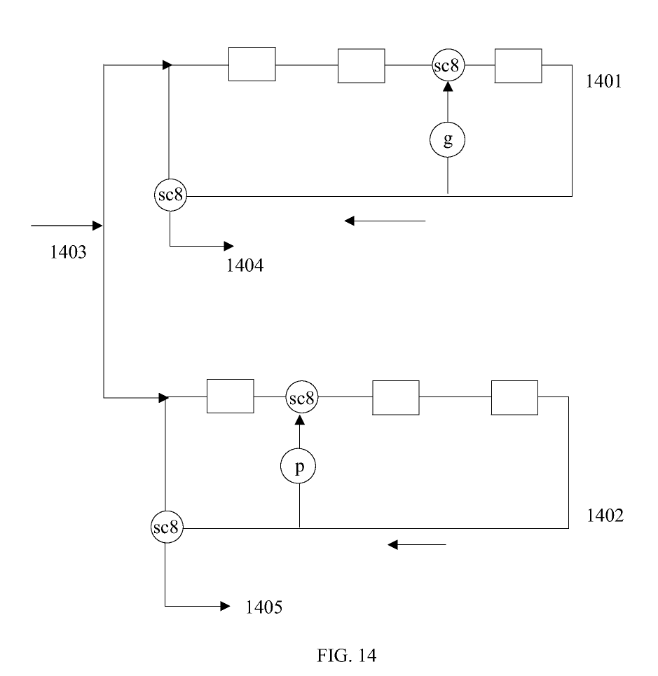

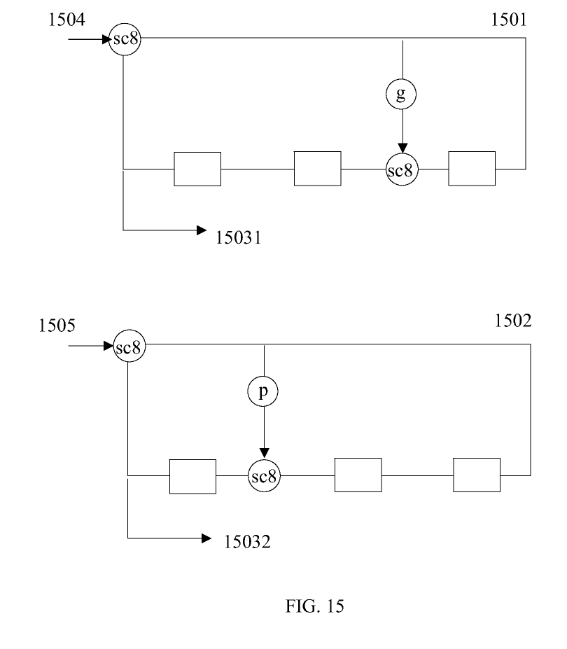

In a further embodiment one may modify the LFSRs or the functions, for instance by including multipliers or reversible n-state inverters. As an illustrative example the previous 8-valued case will be modified to include at least one 8-valued multiplier. For calculating purposes it may be easiest to use one of the multipliers from the function MUL8, though this is not required. FIG. 14 shows as an illustrative example the modified 8-valued coder of FIG. 12 with coders 1401 and 1402 with input 1403 and outputs 1404 and 1405 respectively. Coder 1401 has a multiplier ‘g’ in its feedback tap and coder 1402 has a multiplier ‘p’ in its feedback tap. FIG. 15 shows the corresponding decoders 1501 and 1502 with input 1504 and output 15031 and input 1505 and output 15032 respectively. Decoders 1501 and 1502 also have the multipliers ‘g’ and ‘p’ respectively.

A multiplier ‘g’ is in fact a reversible n-state inverter. The reversing inverter for ‘g’ may be designated as ‘gr’. For instance the multiplier g=5 in MUL8 is the 8-state inverter [0 5 6 7 1 2 3 4]. One may also use an n-state inverter which is not a multiplier over GF(n). Such an inverter does not map input state 0 to input state 0. For instance such an 8-state inverter can be [6 7 1 2 3 4 0 5]. The corresponding n-state reversing inverter is [6 2 3 4 5 7 0 1]. These inverters do not map state 0 to state 0. The same reasoning applies to the n-state functions. The function in the example is an adder over GF(8). Also reversible n-state functions not being an adder over GF(n) can be used. One such function for instance does not map input (0,0) to 0.

The following tables show the solutions for determining the initial states [a1 a2 a3] and [b1 b2 b3] for these coders. One can check that for g=1 and p=1 these solutions become the ones for the coders of FIG. 12.

| input | sr1 |
|---|---|
| s1 | s1 + a3 |
| s2 | s2 + ga3 + a2 |
| s3 | s3 + a1 + g²a3 + ga2 |
| s4 | s4 + s1 + a3 + ga1 + g²a2 + g³a3 |
| s5 | s5 + s2 + ga3 + a2 + gs1 + ga3 + g²a1 + g³a2 + g⁴a3 |
| s6 | s6 + s3 + a1 + g²a3 + gs2 + g²a3 + g²s1 + g²a3 + g³a1 + |
| | g⁴a2 + g⁵a3 |

and

| input | sr1 |
|---|---|
| c1 | c1 + b3 |
| c2 | c2 + b2 |
| c3 | c3 + b1 + pb3 |
| c4 | c4 + c1 + b3 + pb2 |
| c5 | c5 + c2 + b2 + pb1 + p²b3 |
| c6 | c6 + c3 + b1 + pc1 + p²b2 |

The solution matrix then becomes:

| a1 | a2 | a3 | b1 | b2 | b3 | s | or | c | | | | |
|---|---|---|---|---|---|---|---|---|---|---|---|---|
| 0 | 0 | 1 | 0 | 0 | 1 | s1 | c1 | | | | | |
| 0 | 1 | g | 0 | 1 | 0 | s2 | c2 | | | | | |
| 1 | g | g² | 1 | 0 | p | s3 | c3 | | | | | |
| g | g² | g³ + 1 | 0 | p | 1 | s1 | s4 | c1 | c4 | | | |
| g² | 1 + g³ | g⁴ | p | 1 | p² | g*s1 | s2 | s5 | | c2 | c5 | |
| 1 + g³ | g⁴ | g² + g⁵ | 1 | p² | 0 | g²*s1 | g*s2 | s3 | s6 | p*c1 | c3 | c6 |

Substituting g=3 and p=3 and calculating the coefficients will create the solution matrix:

| a1 | a2 | a3 | b1 | b2 | b3 | s | or | c | | | | |
|---|---|---|---|---|---|---|---|---|---|---|---|---|
| 0 | 0 | 1 | 0 | 0 | 1 | s1 | c1 | | | | | |
| 0 | 1 | 3 | 0 | 1 | 0 | s2 | c2 | | | | | |
| 1 | 3 | 5 | 1 | 0 | 3 | s3 | c3 | | | | | |
| 3 | 5 | 3 | 0 | 3 | 1 | s1 | s4 | c1 | c4 | | | |
| 5 | 3 | 2 | 3 | 1 | 5 | 3 * s1 | s2 | s5 | | c2 | c5 | |
| 3 | 2 | 7 | 1 | 5 | 0 | 5 * s1 | 3 * s2 | s3 | s6 | 3 * | c3 | c6 |
| | | | | | | | | | | c1 | | |

The determinant herein has value 2, so one should multiply all results with the reverse which is a factor 7. The 8-valued sequence [1 0 1 1 2 3 1 1 6 0 4 1 1 7] inputted on 1403 will generate [6 5 0 3 0 5 4 0 6 1 5 3 4 7] on 1404 and [2 5 1 7 2 4 0 2 6 5 2 4 7 7] on 1405 when the initial states are [a1 a2 a3]=[3 4 5] and [b1 b2 b3]=[6 5 4].

Accordingly, the provided approach for error correction applies to binary and non-binary LFSRs and switching functions.

LFSRs with More than 1 Feedback Tap

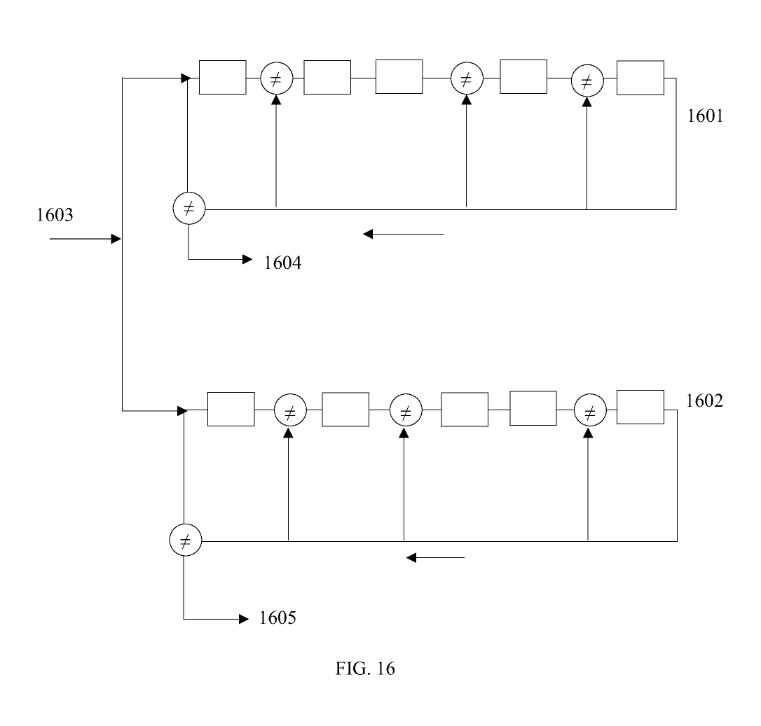

The Galois configuration will provide significant advantages over the Fibonacci configuration when there are 2 or more feedback taps. The approach as provided here may require that an LFSR reflects a primitive polynomial. The two coders of FIGS. 16, 1601 and 1602 represent two primitive polynomials of order 5. The sequence that is to be coded is inputted on input 1603 and the coded sequences are outputted on 1604 and 1605. The generation of the formulas in the solution matrix may become too labor intensive. Especially, because the LFSRs have 5 shift register elements, one requires the solution matrix to be based on 10 consecutive and error-free symbols. While for illustrative purposes the formulas may be useful, they are not required.

In one embodiment one may generate the solution matrix for a coder automatically. The following Matlab code is an illustrative example how to do that.

% generic solution matrix for a Galois convolutional coder

| | |
|---|---|
| xor2=[1 2;2 1]; | % this is the XOR function in origin 1 |

ins=ones(10,15);
for i=1:10

| | |
|---|---|
| ins(i,i)=2; | % these are the 10 generated coded symbols, a |

% symbol s(n) is 2 at moment n and 1 elsewhere

end
shifts1end=ones(10,15);

| | |
|---|---|
| shifts1r=ones(1,15); | % this represents 15 states [s1 s2 s3 s4 s5 s6 |

s7 s8 s9 s10 a1 a2 a3 a4 a5] at moment n=1

| | |
|---|---|
| shifts1r(11)=2; | % this sets the initial state of the first |

element of the shift register
shifts2r=ones(1,15);
shifts2r(12)=2;
shifts3r=ones(1,15);
shifts3r(13)=2;
shifts4r=ones(1,15);
shifts4r(14)=2;
shifts5r=ones(1,15);
shifts5r(15)=2;
for 1=1:10

| | |
|---|---|
| shifts1=plusb(ins(i,:),shifts5r) | % plusb is the vector XOR of |

two vectors

| | |
|---|---|
| shifts2=plusb(shifts1r,shifts5r) | |
| shifts3=shifts2r; | |
| shifts4=plusb(shifts5r,shifts5r); | |
| shifts5=plusb(shifts4r,shifts5r); | |
| shifts1end(i,:)=shifts1; | % the generated output of a |

decoder

| | |
|---|---|
| shifts5r=shifts5; | % the shift operation |
| shifts4r=shifts4; | |
| shifts3r=shifts3; | |
| shifts2r=shifts2; | |
| shifts1r=shifts1; | |

| | |
|---|---|
| end | |
| shifts1end | % the solution matrix |

The above procedure is for one of the two decoders related to the coder of FIG. 16 and can be created for the second decoder also. If it is so desired one can create of course convolutional coders having 3 or more decoders. In essence the above procedure determines the state of each shift register element during each clock cycle. A state of a shift register element is in the above procedure determined by 15 inputs: [s1 s2 s3 s4 s5 s6 s7 s8 s9 s10 a1 a2 a3 a4 a5]. As the shift register is being shifted each new state is determined possibly by a new input (such as sn at moment n) and by previous states, such as [a1 a2 a3 a4 a5], which are the initial states of the shift register.

One can perform the above procedure also for the second decoder. The first and the second decoder then will generate the following solution matrix.

| a1 | a2 | a3 | a4 | a5 | b1 | b2 | b3 | b4 | b5 | s1, s2, . . . s10 | c1, c2, . . . c10 |
|---|---|---|---|---|---|---|---|---|---|---|---|
| 0 | 0 | 0 | 0 | 1 | 0 | 0 | 0 | 0 | 1 | s1 | c1 |
| 0 | 0 | 0 | 1 | 1 | 0 | 0 | 0 | 1 | 1 | s2 | c2 |
| 0 | 0 | 1 | 1 | 0 | 0 | 0 | 1 | 1 | 1 | s3 | c3 |
| 0 | 1 | 1 | 0 | 1 | 0 | 1 | 1 | 1 | 0 | s4 | c4 |
| 1 | 1 | 0 | 1 | 0 | 1 | 1 | 1 | 0 | 0 | s5 | c5 |
| 1 | 0 | 1 | 0 | 1 | 1 | 1 | 0 | 0 | 1 | s1, s6 | c1, c6 |
| 0 | 1 | 0 | 1 | 0 | 1 | 0 | 0 | 1 | 1 | s1, s2, s7 | c1, c2, c7 |
| 1 | 0 | 1 | 0 | 0 | 0 | 0 | 1 | 1 | 0 | s1, s3, s4, s8 | c1, c2, c3, c8 |
| 0 | 1 | 0 | 0 | 1 | 0 | 1 | 1 | 0 | 1 | s1, s3, s4, s9 | c2, c3, c4, c9 |
| 1 | 0 | 0 | 1 | 0 | 1 | 1 | 0 | 1 | 1 | s2, s4, s5, s10 | c3, c4, c5, c10 |

Herein the columns with 0s and 1s determine the unknowns, a1, a2, etc. The terms with s1, s2, c1, c2 determine the solution vector and depend upon the actual value of s1, s2 etc.

To make sure one reads the above solution matrix correctly, one should read for instance the tenth row as: a1≠ a3≠b1≠b2≠b4 ≠b5=s2≠s4≠s5≠s10≠c3≠c4≠c5≠c10, wherein of course a1, a3, b1, b2, b4 and b5 are the unknowns.

By applying the binary modified Cramer's rule or Gaussian elimination one can determine the initial shift register states [a1 a2 a3 a4 a5] and [b1 b2 b3 b4 b5] and one can correct the previous 5 bits in error. An example will be provided.

It should be clear that one can implement binary expressions that will generate directly a solution to Cramer's rule. The above solution matrix is a bit too large to use here as an example. However assume that a system of 3 binary XOR equations yields as a solution

$${x}_{1} = \vert \begin{matrix}s 1 & 1 & 1 \\ s 2 & 0 & 1 \\ s 3 & 1 & 0\end{matrix} \vert = s 1 * \vert \begin{matrix}0 & 1 \\ 1 & 0\end{matrix} \vert + s 2 * \vert \begin{matrix}1 & 1 \\ 1 & 0\end{matrix} \vert + s 3 * \vert \begin{matrix}1 & 1 \\ 0 & 1\end{matrix} \vert = \\ = s 1 * ( 0 + 0 ) + s 2 * ( 0 + 1 ) + s 3 * ( 1 + 0 ) = 0 + s 2 + s 3.$$

In the binary modified Cramer's rule ‘+’ is the XOR function and “*” is the AND function. There is no ‘−’ sign in calculating a binary modified determinant. The symbols s1, s2 and s3 are received coded symbols. One may thus determine the state of a symbol x1 in this example by having a circuit evaluate x₁→s2≠s3, which is a single XOR device with s2 and s3 as inputs and x₁ as output.

One may thus for any solution of any size matrix create a circuit of devices that will generate an appropriate solution output for the correct set of input symbols. One may also determine all solutions for every possible combination and store it in a memory. In the case of the 5 shift register elements LFSRs it would require not more than 1 Mbit in memory.

The coder of FIG. 16 when inputted on 1603 with xin=[1 0 1 1 0 0 1 1 0 0 0 1 1 1 0 0 1] will generate on 1604 sequence [0 1 1 1 1 1 1 1 0 1 1 0 0 0 1 1 1] with initial LFSR state [0 1 0 0 1] and on 1605 sequence [1 1 1 1 0 0 1 0 0 0 1 0 1 0 1 0 1] with initial LFSR state [1 0 1 1 0].

When one has at least 2 corresponding coded sequences of error free symbols one can calculate the initial state of the shift registers at the start of generating those sequences and accordingly the states for the shift registers for decoding the sequences.

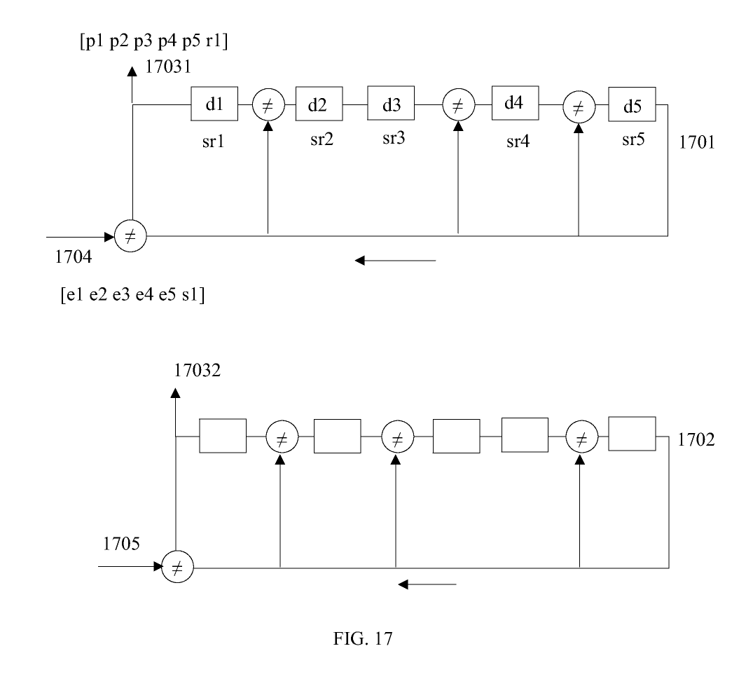

The reason for the ability to correct up to 5 symbols in error is the property of an LFSR to push an inputted symbol or to affect a symbol or state of a shift register of a decoder by one step per clock cycle. For this reason one may apply the bridge effect as was explained above. This bridge effect applies to LFSRs both in Galois configuration and in Fibonacci configuration and applies to binary and to nonbinary LFSRs. This is shown in FIG. 17 with the corresponding decoders 1701 and 1702 of coders 1601 and 1602 of FIG. 16. The coded sequences are inputted on inputs 1704 and 1705 respectively. If everything is error free then outputs 17031 and 17032 will provide the same decoded sequences.

Assume that at a certain moment up to 5 symbols in error [e1 e2 e3 e4 e5] will be provided on 1704 and generate [p1 p2 p3 p4 p5] on output 17031. The content of the shift register at the time that e1 is provided on 1704 is [d1 d2 d3 d4 d5]. After the 5 symbols in error a correct symbol s1 is inputted and generates r1. By using the above method in accordance with an aspect of the present invention, the content of the shift register may be calculated as being [a1 a2 a3 a4 a5]. One can easily see that the 5 shift register elements sr1, sr2, sr3 sr4 and sr5 as of the occurrence of [e1 e2 e3 e4 e5] is dependent on the content [d1 d2 d3 d4 d5] which is fed back from element sr5 into the LFSR and of [e1 e2 e3 e4 e5]. However, before the clock cycle when s1 appears at input 1704, none of the symbols e1, e2, e3, e4 and e5 has reached the shift register element sr5 yet. And thus none of the symbols in errors has yet been fed back into the LFSR. In fact, just when s1 appears, the symbol e1 has influenced the content of sr5. This means that each shift register element up till that moment has been modified by exactly one symbol in error (being shifted in from a previous shift register element) and by a previous content of sr5, which up till that moment only depended on one or more of the states d1, d2, d3, d4 and/or d5, which may be expressed as dₙ={d1, d2, d3, d4, d5}. Accordingly, from the moment an error symbol appears till the moment s1 appears at the input, each shift register element depends on dₙ and on maximally one symbol in error.

In fact one can easily check that when s1 appears at input 1704, then sr1=f1(e5, dₙ)=a1; sr2=f2(e4, dₙ)=a2; sr3=f3(e3, dₙ);=a3; sr4=f4(e2, dₙ);=a4; and sr5=f5(e1, dₙ);=a5. Because all functions in the example are determined by XOR, one can easily determine the value of [e1 e2 e3 e4 e5] or preferably the corrected decoded symbols [p1 p2 p3 p4 p5]. The same simple bridging approach applies to using nonbinary LFSRs and reversible nonbinary logic functions. This approach works with Galois and Fibonacci LFSRs.

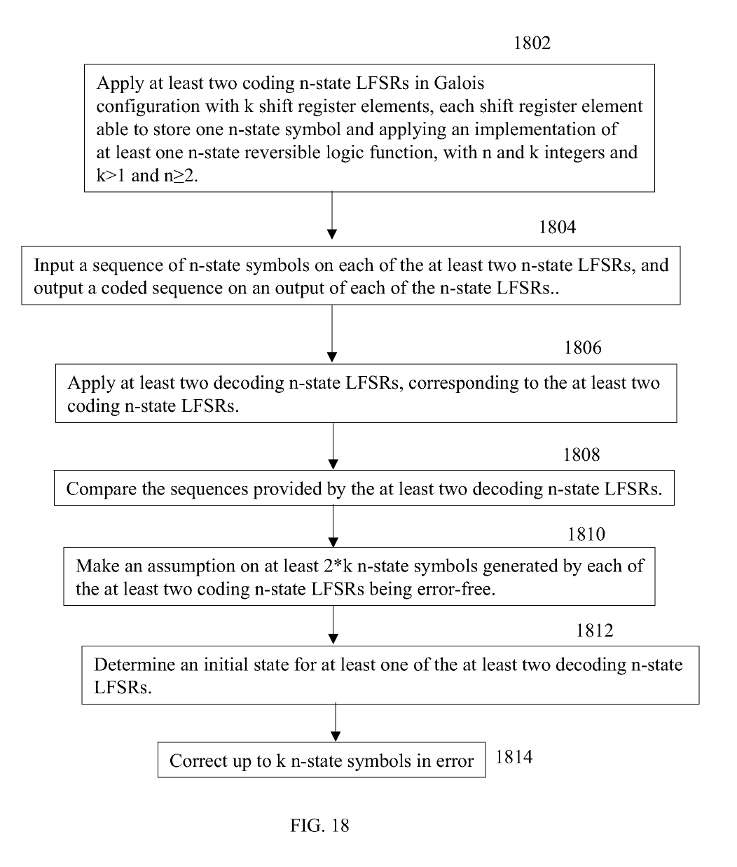

FIG. 18 shows the steps for correcting at least k errors in accordance with an aspect of the present invention. One first applies at least two coding n-state LFSRs in step 1802. While step 1802 shows at least two Galois LFSRs, they may also be at least two Fibonacci LFSRs or a mix of a Fibonacci and a Galois LFSR. N-state in FIG. 18 means one of at least 2 states. In a further embodiment n may also be greater than 2. In step 1804 one codes a sequence of n-state symbols into two coded sequences of n-state symbols with the coding LFSRs. In step 1806 two corresponding decoding LFSRs are applied to the coded sequences to generate two decoded sequences. In step 1808 the two decoded sequences are compared. If decoded sequences are different, one may jump at least k symbols to assume that the coded sequences are error free from that point. In step 1810 one applies 2*k coded symbols from each coded sequence to calculate in 1812 an initial state of at least one of the coders or decoders. In step 1814 one corrects up to k n-state symbols in error.

It is specifically contemplated that n-state LFSRs in one embodiment are implemented in binary form and n-state symbols are implemented as a plurality of binary symbols. The same techniques that are applied to implement for instance Reed Solomon (RS) codes may be applied. In RS coders one may assume a word of for instance 8 bits to represent a 256-state symbol. The shift register elements in an RS coder are able to store and generate words of bits. The n-state switching functions may be defined as for instance adders over GF(2⁸) in the 8-bit word case. An adder over GF(2⁸) can be implemented by 8 XOR functions.

It is further noted that the apparatus and methods provided herein in accordance with an aspect of the present invention, do not require that the coders start from initial state all 0 as required with the standard convolutional codes.

### Correcting Up to K Errors by Applying at Least One LFSR Coded Sequence and a Systematic Sequence

The above methods and apparatus to code, decode and error correct convolutional codes have as additional benefit that the two coded sequences cannot be used without being decoding and thus provide a measure of security. One pays a penalty for this by requiring at least 2*k error-free symbols in both coded sequences, and one has to work with a 2*k by 2*k determinant, or related expressions.

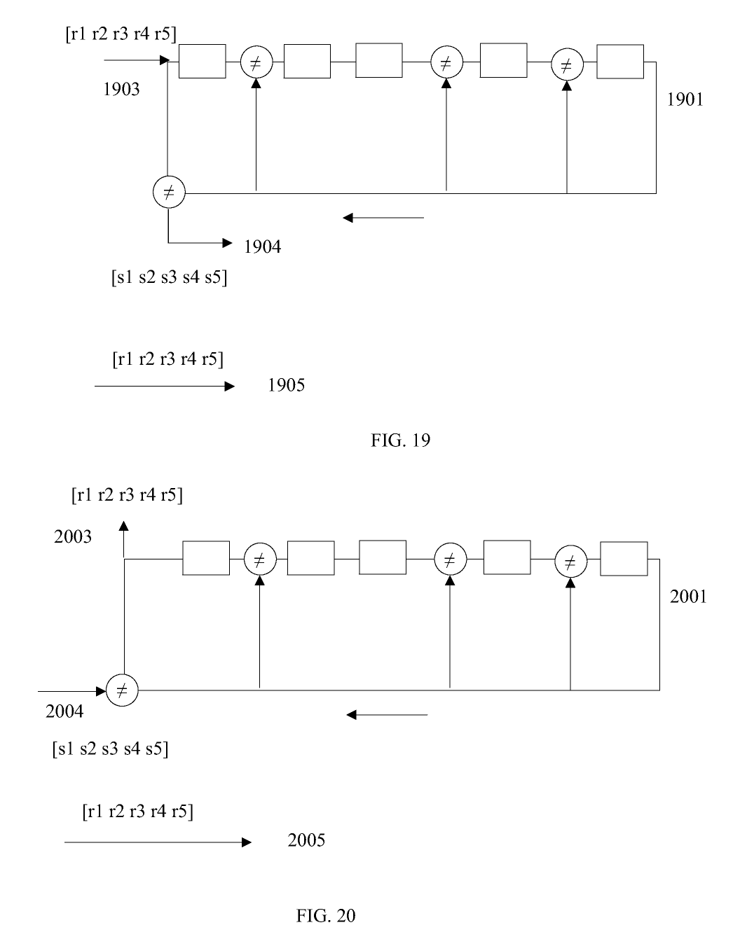

One may create another and potentially a faster error correcting apparatus by providing at least two sequences, wherein the first sequence is an uncoded sequence and the second sequence is a coded sequence. Such a coder is shown in FIG. 19 which shows a single LFSR binary coder 1901 with 5 shift register elements, which may be described by a primitive polynomial of degree 5. It has an input 1903 which receives 5 binary symbols [r1 r2 r3 r4 r5] and generates on output 1904 [s1 s2 s3 s4 s5]. An output 1905 provides the uncoded sequence [r1 r2 r3 r4 r5].

It is noted that the two sequences may be transmitted to a receiver through a single channel, wherein the symbols of the sequences may for instance be multiplexed, such as time multiplexed. The symbol sequences may also be transmitted via different channels, for instance by frequency multiplexing, or by using two different routes through a medium or through different transmission media. Different transmission and modulation techniques are well known and need not to be explained herein. These channel set-ups also apply of course to the above explained methods and systems.

The decoder corresponding to FIG. 19 is shown in FIG. 20 with decoder 2001 being inputted with [s1 s2 s3 s4 s5] on 2004 and outputting the decoded sequence [r1 r2 r3 r4 r5] on 2003. The systematic part of the code is provided on 2005. When the sequences on 2005 and 2003 are the same then it is unlikely that an error has occurred. However, when the sequences are not the same then at least one error has occurred. It may be assumed, based on known or expected performance of a channel that no more than 5 consecutive errors can occur in each sequence and that at least 5 or 6 or more error free symbols occur per sequence. If one cannot guarantee such a performance one may have to create a coder with a longer LFSR. Alternatively, one may create an n-state with n>2 coder with a longer LFSR. Herein the n-state symbols may be represented by binary words.

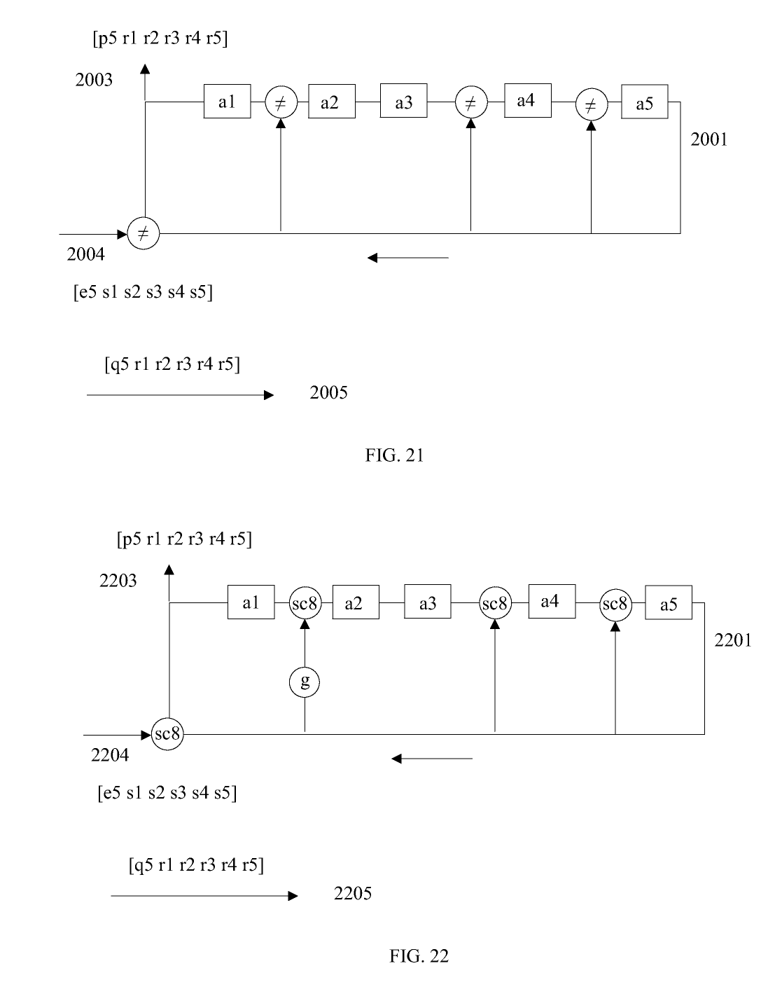

Next the decoding and error correcting process is described for this illustrative example. It is somewhat similar to the earlier provided method, though it requires fewer steps. As was explained before, it takes exactly 5 steps for the errors to reach the last shift register element, once the errors start to occur. In the earlier case one did not know the correct sequence, and one has to equate the results of one decoder with the other decoder. In this case one may assume that the uncoded sequence is error free. This is shown in FIG. 21. The decoder 2001 receives as last error a symbol e5 which will generate p5. This corresponds with symbol q5 in the uncoded sequence. However, from this moment forward [r1 r2 r3 r4 r5] and [s1 s2 s3 s4 s5] may assumed to be error-free, and the decoder may assumed to be decoding correctly starting from shift register state [a1 a2 a3 a4 a5].

The states of the shift register, starting with [a1 a2 a3 a4 a5] are shown in the following table.

| input | output | sr1 | sr2 | sr3 | sr4 | sr5 |
|---|---|---|---|---|---|---|
| | | a1 | a2 | a3 | a4 | a5 |
| s1 | r1→s1 ≠ a5 | r1 | a1 ≠ a5 | a2 | a3 ≠ a5 | a4 ≠ a5 |
| s2 | r2→s2 ≠ a4 ≠ a5 | r2 | r1 ≠ a4 ≠ a5 | a1 ≠ a5 | a2 ≠ a4 ≠ a5 | a3 ≠ a4 |
| s3 | r3→s3 ≠ a3 ≠ a4 | r3 | r2 ≠ a3 ≠ a4 | r1 ≠ a4 ≠ a5 | a1 ≠ a3 ≠ a4 ≠ a5 | a2 ≠ a3 ≠ a5 |
| s4 | r4→s4 ≠ a2 ≠ a3 ≠ a5 | r4 | r3 ≠ a2 ≠ a3 ≠ a5 | r2 ≠ a3 ≠ a4 | r1 ≠ a2 ≠ a3 ≠ a4 | a1 ≠ a2 ≠ a4 |
| s5 | r5→s5 ≠ a1 ≠ a2 ≠ a4 | r5 | r4 ≠ a1 ≠ a2 ≠ a4 | r3 ≠ a2 ≠ a3 ≠ a5 | r2 ≠ a1 ≠ a2 ≠ a3 | r1 ≠ a1 ≠ a3 |

One can see that each output symbol, which is assumed to be correct, can be expressed as a function of an initial state and a coded symbol. The coded symbols are also assumed to be correct, and accordingly one can establish equations to solve the initial state [a1 a2 a3 a4 a5]. One may apply a modified Cramer's rule. One may also work back from a5→r1≠s1 to a4, etc. by substituting the calculated symbols in the next one. Accordingly one can solve [a1 a2 a3 a4 a5].

One can now resolve the symbols in error by the ‘bridging’ approach as explained before.

In a further embodiment one may use an n-state LFSR wherein the ‘≠’ function is replaced by an adder over GF(2^{k}) with k>1. It is known to one of ordinary skill in the art that such adders are self-reversing, commutative and associative, so that the above expressions modified for such adder can be applied.

In a further embodiment one may apply any n-state LFSR with an implementation of an adder over GF(2^{k}) with k>1 logic function and an implementation of an n-state reversible inverter.

In a further embodiment one may apply any n-state LFSR with an implementation of a reversible n-state logic function which is an adder over GF(n) or is not an adder over GF(n). This is illustrated in FIG. 22 where an n-state decoder 2201 is shown with an n-state LFSR and implementations of a function sc8. In an illustrative example sc8 may be an adder over GF(8) as shown earlier. Furthermore, a multiplier ‘g’ is included in the first tap of the LFSR. In a further embodiment an n-state reversible inverter not being a multiplier is used. A coded sequence is entered on 2204 and a decoded sequence of n-state symbols is provided on 2203. Because FIG. 22 shows a systematic decoder an uncoded sequence is also provided on 2205. The output equations are provided in the following table.

| input | output |
|---|---|
| s1 | r1→s1 + a5 |
| s2 | r2→s2 + a4 + a5 |
| s3 | r3→s3 + a3 + a4 |
| s4 | r4→s4 + a2 + a3 + a5 |
| s5 | r5→s5 + a1 + a2 + a4 + (g + 1)*a5 |

In the table ‘+’ is sc8, which may be an adder over GF(8) also called an extension Galois field, of which the truth table was provided earlier. The only part that seems to be troublesome is the last equation: r5→s5+a1+a2+a4+(g+1)*a5. However, one may solve the equations with the truth tables as provided. For instance assume that g=3. The truth table of ‘MUL8 ’ provides the related switching states. When g=3, then g+1=7 according to the truth table of ‘sc8 ’. One may reduce r5→s5+a1+a2+a4+(g+1)*a4 to r5→s5+a1+a2+a4+7*a4. Or r5+s5+a1+a2+a4=7*a5. The reverse of multiplying by 7 in MUL8 is multiplying by two as 2*7=1 in GF(8). This leads to a5=2*(r5+s5+a1+a2+a4). However, in general one would want to use the expression r5→s5+a1+a2+a4+(g+1)*a5 to determine a1. This leads to a1=r5+s5+a2+a4+(g+1)*a5.

Accordingly, one may also determine in any n-state systematic decoder with n>2 with an LFSR with k n-state shift register elements the initial state by applying k uncoded and k coded n-state symbols which are error free and correct up to k symbols errors.

Or, in general: one can in a systematic n-state LFSR decoder with n>1 and with the n-state LFSR having k with k>1 shift register elements enabled to store an n-state symbol, determine the initial state of the LFSR and correct up to k n-state symbols in error.

As an illustrative example one may use the 8-state coder related to the decoder of FIG. 22 with g=3 and sc8 is an adder over GF(8). Assume the initial state of the LFSR to be [3 4 5 02] and the inputted and systematic sequence being xin=[1 0 1 1 2 3 1 1 6 0 4 1 1 7 3 1 1 6 0 4] and the coded sequence out=[4 2 6 5 3 6 1 2 0 1 1 3 5 3 1 3 1 6 6 2].

An easy example is then to take the first 5 symbols from xin1=[r1 r2 r3 r4 r5]=[1 0 1 1 2] and out1=[s1 s2 s3 s4 s5]=[4 2 6 5 3] and check if this generates the correct initial state of the shift register by using the above expressions.

The following equations apply:

a5=r1+s1=(4+1)=2;

a4=r2+s2+a5=(0+2+2)=0;

a3=r3+s3+a4=(1+6+0)=5;

a2=r4+s4+a3+a5=(1+5+5+2)=4; and

a1=r5+s5+a2+a4+7*a5=(2+3+4+0+7*2)=3.

This leads to [a1 a2 a3 a4 a5]=[3 4 5 0 2] as the initial content of the shift register, which is of course correct. One may obtain the same result by applying the 8-state modified Cramer's rule with 5 unknowns.

One can modify the herein provided systematic encoder with one uncoded sequence and one coded sequence to a systematic coder that applies a coder with a Fibonacci LFSR. It should be clear that if one demonstrates such a coder and decoder for an n-state LFSR with at least one n-state functions and an n-state inverter that it is also demonstrated for the much easier n-state case having no inverter and for the binary case.

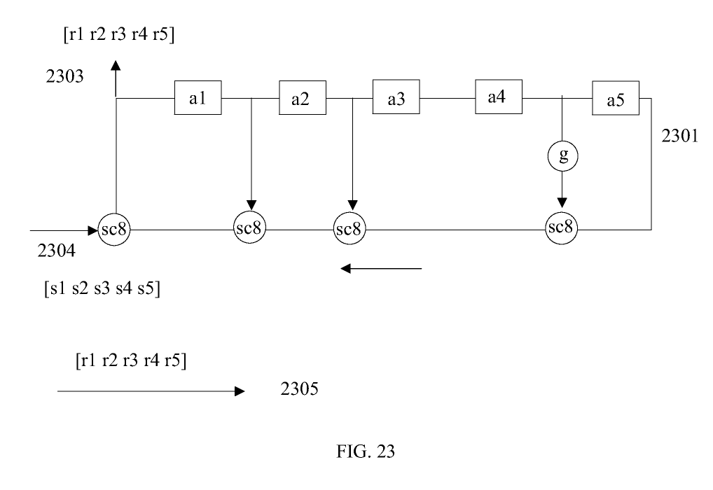

FIG. 23 shows in diagram the n-state decoder in Fibonacci configuration 2301 corresponding with an n-state coder and having an input 2304 for entering a coded n-state sequence and an output 2303 for providing the decoded sequence. An uncoded sequence is provided on 2305. The decoder has an n-state inverter g in one tap. An illustrative example will be provided for n=8.

The solution equation for the decoder 2301 are:

r1=s1+a1+a2+g*a4+a5;

r2=s2+r1+a1+g*a3+a4;

r3=s3+r2+r1+g*a2+a3;

r4=s4+r3+r2+g*a1+a2;

r5=s5+r4+r3+g*r1+a1;

An 8-state LFSR coder corresponding to the decoder of FIG. 23 and with an initial shift register state of [3 4 5 0 2] and g=3 and xin=[1 0 1 1 2 3 1 1 6 0 4 1 1 7 3 1 1 6 0 4] will generate a coded sequence out=[3 0 1 7 2 5 4 1 7 2 3 6 4 2 6 6 1 3 7 3]. One can then check the above approach by using an input sequence [r1 r2 r3 r4 r5]=[1 0 1 1 2] and generated sequence [s1 s2 s3 s4 s5]==[3 0 1 7 2] which are the first 5 symbols of the above sequences. Determining the initial state [a1 a2 a3 a4 a5] must provide [3 4 5 0 2]. One may apply the 8-state modified Cramer's rule. One may also start by calculating a1 and then substituting a1 in the other equations. The equations and solutions then are:

a1=r5+s5+r4+r3+3*r1=(2+2+1+1+3*1)=3;

a2=r4+s4+r3+r2+3*a1=(1+7+1+0+3*3)=(7+5)=4;

a3=r3+s3+r2+r1+3*a2=(1+1+0+1+3*4)=(1+6)=5;

a4=r2+s2+r1+a1+3*a3=(0+0+1+3+3*5)=(7+7)=0; and

a5=r1+s1+a1+a2+3*a4=(1+3+3+4+3*0)=(1+4)=2.

This is of course correct. Keep in mind that “*” is provided by MUL8 and ‘+’ by ‘sc8 ’. Error correcting is very simple. The previous 5 correct symbols are [a5 a4 a3 a2 a1], as shifted into the Fibonacci LFSR.

Correcting More than K Errors with at Least One n-State Galois/Fibonacci Coders with k and n Integers and k>1 and n>1

It was shown above that one may correct up to k errors in a sequence of n-state symbols with n>1 with at least one n-state LFSRs with k>1 and one uncoded sequence or with at least two LFSRs and the LFSRs being either Galois or Fibonacci. It is one condition for bridging that at most k consecutive n-state symbols are in error. In the Fibonacci configuration one may still correct k symbols in error even if more than k consecutive symbols were in error. However, bridging is no longer possible.

In many cases the error performance of a channel can be estimated, and it is possible to determine that for most of the time (99.999% for instance) no more than k consecutive errors will occur. Even with a high Bit Error Ratio (BER) it is then possible to correct multiple errors as long as at one point 2*k or k symbols (depending on the manner of coding) are error free in each sequence.

It should be clear that in the case of the systematic LFSR coder after at most k n-state symbols in error at least k n-state symbols are error-free and in the case of 2 LFSR coders after at most k n-state symbols in error at least 2*k n-state symbols are error-free, then one may correct multiple occurrences of errors.

The LFSRs as provided herein all have the appropriate signals provided to make them work properly. For instance, for a binary or n-state shift register to work, a clock pulse may be provided to have a shift register element enter a new n-state symbol and have the new symbol replace a previous symbol. Clock circuitry to achieve the enter-and-shift is known and is fully contemplated. To make the drawings as un-cluttered as possible the lines and circuitry proving a clock pulse are not shown, but should specifically be assumed.

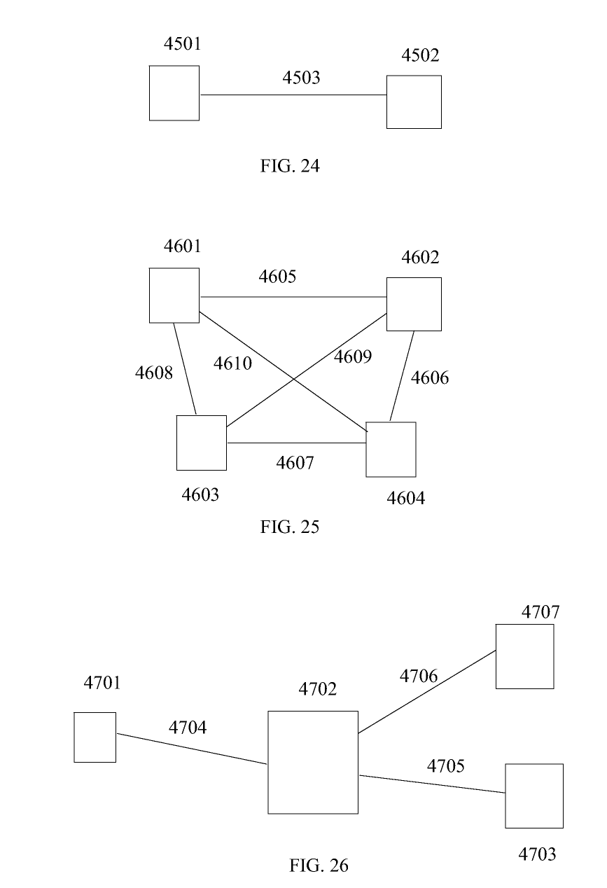

The scrambling and descrambling, coding, decoding and error correcting and calculation methods and apparatus as provided herein as an aspect of the present invention may be part of a system. This may include: a communication system, which may be a cellular telephone system, a data storage system or any other system for coding, or transmitting, or storing, or receiving, or retrieving, or decoding or any other system for processing data. The system may be a wired or a wireless system, such as a cell phone system. A data storage system may be a system using an optical disk, or an electro-optical disk. It may also use a magnetic medium. Symbols may be represented as optical, electronic or any other valid representation that can be processed, including magnetic. In accordance with a further aspect of the present invention a communication system is provided for communication between at least two apparatus, at least two apparatus applying one or more of the methods provided in accordance with one or more aspects of the present invention. A diagram of such a system in a first embodiment is shown in FIG. 24 and has two apparatus 4501 and 4502. However it may have more apparatus also. An apparatus may be a telephone, for instance a mobile phone. An apparatus may also be a personal computer or any other computing device. An apparatus should comprise circuitry for receiving and/or sending of signals. For instance 4501 may be a remote control able to transmit data and 4502 a receiver, able to receive data. The connection 4503 can be a wireless connection or a wired connection, suitable for transmitting data.

A further system embodiment is shown in FIG. 25, wherein more than 2 apparatus are present to use one or more methods in accordance with the different aspects of the present invention. An embodiment as shown in diagram in FIG. 25 may be a peer-to-peer network wherein none of the 4 apparatus 4601, 4602, 4603 and 4604 shown as an illustrative example have inherent priority for communication, except perhaps rules that an apparatus may finish communicating once it has started. The protocol of such a network may be: all-connected-to-all with connections 4605, 4606, 4607, 4608, 4609 and 4610, such as in a radio connection; it may also be that some type of ring network is used, wherein for instance only 4605, 4606, 4607 and 4608 are used. Herein all the apparatus will perform one or more aspects of the present invention.

Yet a further embodiment of a system is shown in diagram in FIG. 26. Herein at least 3 apparatus are included: an apparatus 4701 to communicate with apparatus 4703 and network apparatus 4702. Communication takes place over a network that has connections 4704 and 4706. Furthermore, one or more apparatus 4702 may be included in the transmission way to facilitate transmission. Accordingly 4704, 4702, and 4705 may represent all aspects of a network, including switches, servers, routers, modems and other equipment for completing transmitting signals between 4701 and 4703. In many cases an apparatus 4701 can also communicate with other apparatus such as 4707, which includes a path 4706. The network is thus not limited to only two communicating apparatus but may include one more or for instance 1000s more. However two apparatus when communicating should be aware of each other's use of methods according to the different aspects of the present invention, in order to correctly decode signals and correct errors for instance. One or more aspects of the coding/decoding and error correction methods may be present in network apparatus such as 4702. One or more aspects of the present invention are present in at least two apparatus of the network.

An n-valued symbol may be represented as a single or a composite signal having physical properties of for example different amplitude, phase, modulation, polarization or any other quantifiable physical property. Switching tables may be realized in electronic, optical, electro-optical, electro-mechanical, quantum mechanical or any other way that can implement an n-valued truth table. A symbol may also be represented by a series of lower valued symbols such as binary symbols. Switching and storage of symbols then take effect on the series of symbols, often called words.

One may implement n-state switching devices in several ways. One way is disclosed by the inventor in U.S. Pat. No. 7,218,144 issued on May 15, 2007, and in U.S. patent application Ser. No. 11/964,507 filed on Dec. 26, 2007 which are both incorporated herein by reference in their entirety. It is also possible to represent an n-state symbol with n>2 by for instance binary words. For instance, an 8-state symbol may be represented by a word of 3 bits. An n-state symbol may then be generated as a single signal by inputting for instance a Digital/Analog converter with a three bits word to generate a single signal for instance having an amplitude having one of 8 states for instance 0, 1, 2, 3, 4, 5, 6 and 7 representing a state indicated by a 3-bits word. One may convert a symbol represented by a single signal enabled to assume one of n states into a binary word. One may implement any n-state truth table in a binary circuit. One may thus convert with one or two Analog/Digital converters one or more n-state signals to one or more binary words; provide the one or more n-state symbols as binary words to a binary circuit implementing an n-state truth table; having the circuit generate at least a binary word as a result; and having the generated binary word converted by a D/A converter into an n-state signal.

For practical reasons it may be efficient to consider a sequence of binary symbols as representing a sequence of binary words, which may be processed by at least one n-state logic function implemented in binary form.

A binary or n-state function that is an inverter may be called a one-place function. A device that implements such a function in general has only a functional input and a functional output, though it may have inputs for power supply and the like. Such one-place functions are determined by a 1 by n truth table for an n-state inverter and a 1 by 2 truth table for a binary inverter. An n-state or binary switching or logic function that can be defined by an n by m truth table with m≧n and n≧2 may be called a 2-place function as it has two inputs (and one output). It may also be called a 2-place logic function, or a 2-place n-state logic function. In the binary case such a function may be called a 2-place binary logic function. XOR and EQUIVALENCE are both reversible binary 2-place functions.

A connection between two connection points herein may be a straight connection. One may also say the connection is formed by an Identity Inverter or an Identity one-place logic function; for instance in the binary case [0 1]→[0 1]. A connection is herein also considered to be a connection that includes a reversible one-place function that is not an Identity Inverter; for instance in the binary case [0 1]→[1 0] is considered herein a connection. In a connection in the n-state case with n>2 wherein the one-place logic function in a connection is not reversible, but does not provide one constant output, is also considered to be a connection. A one-place logic function that provides one constant output, for instance [0 1]→[0 0] is not considered to be a connection. Accordingly, an output that is connected to an input, or an input that is connected to another input and the like may contain an inverter; it may also contain not an inverter.

The steps of the methods which are provided as aspects of the present invention may be implemented in a processor; such a processor may be a general purpose processor or for instance a digital signal processor or a microprocessor. Such a processor may process binary symbols or signals. It may also process n-valued symbols. It may also process n-state symbols as words of binary symbols or signals. They may use A/D and D/A converters to change n-valued symbols in words of lower valued symbols and to convert words of lower valued symbols into n-valued symbols. In case an n-valued symbol is represented as a word of lower valued symbol a storage element of a shift register is assumed to be able all elements of a word representing an n-valued symbol. The n-valued symbols may also be processed by dedicated or custom made switching and storage components. The methods and apparatus may also be implemented in standard binary components, or in programmable devices such as Field Programmable Gate Arrays (FPGAs) or in any other device that will process signals in accordance with one or more aspects of the present invention. While electronic devices are common, aspects of the present invention may also be processed by other type of signals, including optical, chemical, bio-chemical, biological and/or quantum mechanical representation of symbols.

One may also implement LFSRs by using addressable memories and Look-up Tables. N-valued switching functions can be implemented in different ways. One way is to apply a memory based switching table having the states of the switching function. Signals can be n-valued digital or discrete signals. They can also be represented in binary form. N-valued switching here means any form of n-valued switching and can for instance be achieved in electronic form, in optical form, in electromechanical form or any form where n-valued output states can be achieved from one or more n-valued input states. The different aspects of the present invention can be implemented as instructions on a processor, and a memory enabled to store and provide instructions and data to the processor, in dedicated switching applications or any other means that can realize n-valued switching functions and data retaining elements. Binary LFSRs, coders, decoders and circuits can be implemented of course by using well known binary electronic devices, processors and memory.

LFSRs are generally implemented with shift register element. A new content of shift register element is commonly determined from a content of a preceding shift register element. This type of implementation requires a true shift register or a circuit that simulates the steps of a shift register. It should be clear that any n-state LFSR is a deterministic device. Any state of any shift register element is completely determined by previous states and externally provided signals. Accordingly, one can calculate any state of any shift register element for any stable moment in its operation by an n-state expression that uses initial states of the LFSR and externally provided n-state symbols as inputs. In one embodiment one may evaluate expressions in parallel by a parallel processing device architecture. For instance a processor or a processing device may be dedicated to evaluate a single expression. This enables concurrent evaluation of several LFSR states or of a concurrent state of each shift register element in an LFSR. This means that a circuit does not have to run through all intermediate states of an LFSR. This circumvents the latency that is inherent to LFSRs. One can thus perform the coding and decoding which are provided herein by applying a binary or n-state LFSR. One can also perform the coding and decoding with expressions that are associated with a binary or n-state LFSR. A coder and/or decoder is thus enabled by implementing a binary or n-state LFSR or by evaluating binary or n-state expressions that are associated with a binary or n-state LFSR. It was shown earlier that evaluating a binary or an n-state expression can be reduced to a binary or n-state switching device which is inputted with one or more signals representing one or more symbols (binary or n-state) and at least one output that provides a signal representing the result of the binary or n-state expression.

It is pointed out that for convenience the terms scrambler and descrambler are applied herein. A scrambler is generally understood to be at the sending side and a descrambler at the receiving side. It is pointed out that one may scramble with apparatus that is called herein a descrambler, and one may descramble with an apparatus that is called herein a scrambler. The self-synchronizing aspect of what is called a descrambler may be lost if one uses a what is called herein a scrambler to descramble. However, if one is able to provide corresponding initial conditions as they relate to scramblers and descramblers, reversal of their roles should not be a problem. Reversal of those roles is explicitly and fully contemplated as an aspect of the present invention.

For illustrative purposes the binary function provided in the examples is the binary XOR function. One may replace the XOR function with the binary EQUIVALENCE function. Furthermore, where possible a binary inverter [0 1]→[1 0] may be inserted without fundamentally changing the herein provided approach. The n-state functions provided herein may be self-reversing. They may also be reversible but non self-reversing. They may also be commutative. They may also be non-commutative. Where possible an n-state reversible inverter may also be inserted.

Examples herein are provided with relatively small shift registers with 3, 4 or 5 register elements. It is to be understood that this is done to limit the complexity of the examples. One may apply shift registers with greater than 4 shift register elements.

The coders and decoders provided herein in one embodiment on sequences with a low clock rate of around 1 symbol per second. However, even with that low processing rate a human would not be able to process and error correct n-state symbols according to methods provided herein. In a further embodiment n-state symbols with n>2 and a further embodiment with n>2, are processed at processing speeds that are higher than 1 symbol per second. In one embodiment the processing speed is greater than 50 symbols per second. In another embodiment the speed is higher than 100 symbols per second. In yet another embodiment the processing speed is higher than 1,000,000 n-state symbols per second. One is reminded that a clock speed of a processor has to be higher than the symbol speed, as the decoding requires the execution of a plurality of steps.

In one embodiment, a decoder works in real-time. This means that no noticeable delay that would for instance violate the Shannon-Nyquist sampling theorem will occur due to delay in the decoder.

While the invention has been described with reference to an illustrative embodiment, this description is not intended to be construed in a limiting sense. For example, while the disclosed embodiments utilize discrete devices, these devices can be implemented using one or more appropriately programmed processors, special-purpose integrated circuits, digital processors, programmable logic devices, memory devices or an analog or hybrid counterpart of any of these devices.

The following patent applications, including the specifications, claims and drawings, are hereby incorporated by reference herein, as if they were fully set forth herein: (1) U.S. Non-Provisional patent application Ser. No. 10/935,960, filed on Sep. 8, 2004, entitled TERNARY AND MULTI-VALUE DIGITAL SCRAMBLERS, DESCRAMBLERS AND SEQUENCE GENERATORS; (2) U.S. Non-Provisional patent application Ser. No. 10/936,181, filed Sep. 8, 2004, entitled TERNARY AND HIGHER MULTI-VALUE SCRAMBLERS/DESCRAMBLERS; (3) U.S. Non-Provisional patent application Ser. No. 10/912,954, filed Aug. 6, 2004, entitled TERNARY AND HIGHER MULTI-VALUE SCRAMBLERS/DESCRAMBLERS; (4) U.S. Non-Provisional patent application Ser. No. 11/042,645, filed Jan. 25, 2005, entitled MULTI-VALUED SCRAMBLING AND DESCRAMBLING OF DIGITAL DATA ON OPTICAL DISKS AND OTHER STORAGE MEDIA; (5) U.S. Non-Provisional patent application Ser. No. 11/000,218, filed Nov. 30, 2004, entitled SINGLE AND COMPOSITE BINARY AND MULTI-VALUED LOGIC FUNCTIONS FROM GATES AND INVERTERS; (6) U.S. Non-Provisional patent application Ser. No. 11/065,836 filed Feb. 25, 2005, entitled GENERATION AND DETECTION OF NON-BINARY DIGITAL SEQUENCES; (7) U.S. Non-Provisional patent application Ser. No. 11/139,835 filed May 27, 2005, entitled Multi-Valued Digital Information Retaining Elements and Memory Devices; (8) U.S. Non-Provisional patent application Ser. No. 12/137,945 filed on Jun. 12, 2008, entitled Methods and Systems for Processing of n-State Symbols with XOR and EQUALITY Binary Functions; (9) U.S. Non-Provisional patent application Ser. No. 11/679,316, filed on Feb. 27, 2007, entitled METHODS AND APPARATUS IN FINITE FIELD POLYNOMIAL IMPLEMENTATIONS; (10) U.S. Non-Provisional patent application Ser. No. 11/696,261, filed on Apr. 4, 2007, entitled BINARY AND N-VALUED LFSR AND LFCSR BASED SCRAMBLERS, DESCRAMBLERS, SEQUENCE GENERATORS AND DETECTORS IN GALOIS CONFIGURATION; (11) U.S. Non-Provisional patent application Ser. No. 11/964,507 filed on Dec. 26, 2007, entitled IMPLEMENTING LOGIC FUNCTIONS WITH NON-MAGNITUDE BASED PHYSICAL PHENOMENA; (12) U.S. Non-Provisional patent application Ser. No. 12/273,262, filed on Nov. 18, 2008, entitled Methods and Systems for N-state Symbol Processing with Binary Devices; (13) U.S. patent application Ser. No. 11/566,725, filed on Dec. 5, 2006, entitled ERROR CORRECTING DECODING FOR CONVOLUTIONAL AND RECURSIVE SYSTEMATIC CONVOLUTIONAL ENCODED SEQUENCES; (14) U.S. patent application Ser. No. 11/555,730 filed on Nov. 2, 2006, entitled SCRAMBLING AND SELF-SYNCHRONIZING DESCRAMBLING METHODS FOR BINARY AND NON-BINARY DIGITAL SIGNALS NOT USING LFSRs; (15) U.S. patent application Ser. No. 11/680,719 filed on Mar. 1, 2007, entitled MULTI-VALUED CHECK SYMBOL CALCULATION IN ERROR DETECTION AND CORRECTION; and (16) U.S. patent application Ser. No. 11/739,189 filed on Apr. 24, 2007, entitled ERROR CORRECTION BY SYMBOL RECONSTRUCTION IN BINARY AND MULTI-VALUED CYCLIC CODES.

While there have been shown, described and pointed out fundamental novel features of the invention as applied to preferred embodiments thereof, it will be understood that various omissions and substitutions and changes in the form and details of the device illustrated and in its operation may be made by those skilled in the art without departing from the spirit of the invention. It is the intention, therefore, to be limited only as indicated by the scope of the claims appended hereto.

1. A method for decoding with a processor a first coded sequence of p n-state symbols with p and n being integers greater or equal to 2, comprising:
generating the first coded sequence from a second sequence of p n-state symbols by a first coder associated with a first n-state Linear Feedback Shift Register (LFSR) in Galois configuration with k shift register elements, k being an integer greater than 1, each n-state symbol in the first coded sequence being represented by a signal;
determining a start state of a first decoder corresponding to the first coder by processing at least k symbols of the first coded sequence and at least k symbols of a third sequence related to the second sequence; and
decoding the first coded sequence into a first decoded sequence with the first decoder by applying the start state.

2. The method as claimed in claim 1, wherein the third sequence is identical to the second sequence.

3. The method as claimed in claim 1, wherein:
the third sequence is generated from the second sequence by a second coder associated with a second n-state Linear Feedback Shift Register (LFSR) having at least k shift register elements; and
determining a start state of the first decoder by processing at least 2*k symbols of the first sequence and at least 2*k symbols of the third sequence.

4. The method as claimed in claim 1, further comprising:
storing a first state of the first decoder when corresponding symbols in the first coded sequences and the second sequence indicate an error; and
correcting up to k n-state symbols in error in a sequence of n-state symbols by processing the first state and the start state by the processor.

5. The method as claimed in claim 1, wherein an n-state symbol is represented by an n-state signal able to assume one of n states.

6. The method as claimed in claim 1, wherein an n-state symbol is represented by a binary word, and a decoder is implemented by using binary circuitry.

7. The method as claimed in claim 1, wherein n>2.

8. The method as claimed in claim 1, wherein the method is applied in a communication system.

9. The method as claimed in claim 1, wherein the method is applied in a data storage system.

10. A method for decoding with a processor a first coded sequence of p n-state symbols with p and n being integers greater or equal to 2, comprising:
generating the first coded sequence from an uncoded sequence of p n-state symbols by a first coder equivalent to a first n-state descrambler with a first n-state Linear Feedback Shift Register (LFSR) in Fibonacci configuration having k shift register elements with k being an integer greater than 1;
determining a start state of a first decoder corresponding to the first coder by processing k symbols of the first coded sequence and k symbols of the uncoded sequence; and
decoding the first coded sequence into a first decoded sequence with the first decoder by applying the start state.

11. A system for decoding a first coded sequence of p n-state symbols with p and n being integers greater or equal to 2, comprising:
a memory for storing and retrieving data and instructions;
a processor for executing instructions to performs the steps of:
generating the first coded sequence from an uncoded sequence of p n-state symbols by a first coder associated with a first n-state Linear Feedback Shift Register (LFSR) in Galois configuration having k shift register elements with k being an integer greater than 1;
determining a start state of a first decoder corresponding to the first coder by processing at least k symbols of the first coded sequence and at least k symbols of a second sequence related to the uncoded sequence; and
decoding the first coded sequence into a first decoded sequence with the first decoder by applying the start state.

12. The system as claimed in claim 11, wherein the second sequence is the uncoded sequence.

13. The system as claimed in claim 11, wherein:
the second sequence is generated from the uncoded sequence by a second coder associated with a second n-state Linear Feedback Shift Register (LFSR) having at least k shift register elements with k being an integer greater than 1; and
determining a start state of the first decoder by processing at least 2*k symbols of the first coded sequence and at least 2*k symbols of the second sequence.

14. The system as claimed in claim 11, further comprising instructions to perform:
storing a first state of the first decoder when corresponding symbols in the first coded sequences and the second sequence indicate an error; and
correcting up to k n-state symbols in error in a sequence of n-state symbols by processing the first state and the start state by the processor.

15. The system as claimed in claim 11, wherein an n-state symbol is represented by an n-state signal able to assume one of n states.

16. The system as claimed in claim 11, wherein an n-state symbol is represented by a binary word, and a decoder is implemented by using binary circuitry.

17. The system as claimed in claim 11, wherein n>2.

18. The system as claimed in claim 11, wherein the system is part of a communication system.

19. The system as claimed in claim 11, wherein the system is part of a wireless communication system.

20. The system as claimed in claim 1, wherein the system is applied in a data storage system.
